(19) United States
(12) Patent Application Publication
(10) Pub. No.: US 2026/0362840 A1
(43) Pub. Date: Nov. 12, 2026

(54) SENSOR STACK FOR 3D DETECTOR SYSTEM

(71) Applicant: SiSnap AB, Stockholm (SE)

(72) Inventors: Mats DANIELSSON, Täby (SE); Moa YVEBORG TAMM, Hägersten (SE); Luca TERENZI, Solna (SE)

(73) Assignee: SiSnap AB, Stockholm (SE)

(21) Appl. No.: 19/200,345

(22) Filed: May 6, 2025

(51) Int. Cl. H10F 39/95; G01T 1/164; G01T 1/29; H10F 39/00; H10F 39/18; H10F 77/122; H10F 77/16; H10W 90/00

(52) U.S. Cl. CPC H10F 39/95; G01T 1/1642; G01T 1/2985; H10F 39/18; H10F 39/811; H10F 77/122; H10F 77/16; H10W 90/00

(57) ABSTRACT

A sensor stack for molecular imaging of an object emitting radiation from radioactive nucleotides comprises multiple sensor pair superimposed on top of each other. Each sensor pair comprises two sensor chips two sensor chips having a pixelized main side comprising a plurality of pixels and integrated CMOS electronic and an opposite high voltage main side. A respective connector is connected to the integrated electronics of the sensor chips. The two sensor chips are superimposed on top of each other with the high voltage main sides facing. A connector board is electrically connected to the connectors of the multiple sensor pairs in the sensor stack. A 3D detector comprises a plurality of such sensor stack.

### TECHNICAL FIELD

The present invention generally relates to a sensor stack for molecular imaging of an object emitting radiation from radioactive nucleotides, and a three-dimensional (3D) detector system for molecular imaging of radioactive nuclides comprising a plurality of such sensor stacks.

### BACKGROUND

In molecular imaging, radiolabeled biologically relevant probes are used as tracers, also referred to as radiotracers, to map biological function and processes in the body. To measure the location of the radioactive nuclides, also referred to as radionuclides, radioisotopes or radioactive isotopes in the art, the incident direction of the detected photons needs to be measured. For this, in positron emission tomography (PET), two 511 keV photons from the positron annihilation are detected in time coincidence and the radionuclide is assumed to be on the line between the two points where the photons were detected. In single photon emission computed tomography (SPECT), the individual photons emitted from the radionuclide must pass through a collimator with holes that define the allowed incident directions. The detector positioned behind the collimator determines the detected position of the small fraction of the photons that make it through the collimator.

Both PET and SPECT are widely used for clinical imaging and for research, each having its own advantages and challenges. For instance, PET is fundamentally limited in resolution due to the positron range (0.5-6 mm) and requires expensive cyclotrons in the vicinity to produce the radionuclides. The problem with SPECT systems is the mechanical collimator, which is very inefficient, rejecting most of the photons that carry information about the object, with only about 1 out of 10⁶ photons passed to the detector. The collimators used in SPECT systems have an unfortunate built-in trade-off between efficiency and spatial resolution, limiting the latter to around 10 mm.

There is therefore a need for a 3D detector system that can be used for molecular imaging of radioactive nuclides and that is not marred by the shortcomings of existing PET and SPECT systems.

### SUMMARY

It is a general objective a detector system having high efficiency and spatial resolution.

It is a particular objective to provide a sensor stack used as building block for a 3D detector of a detector system.

These and other objectives are met by embodiments as disclosed herein.

An aspect of the invention relates to a sensor stack for molecular imaging of an object emitting radiation from radioactive nucleotides. The sensor stack comprises multiple sensor pairs superimposed on top of each other. Each sensor pair of the multiple sensor pairs comprises a first sensor chip made of silicon and comprising a pixelized main side comprising a plurality of pixels and integrated CMOS electronics electrically connected to the plurality of pixels, and a high voltage main side opposite to the pixelized main side. Each sensor pair also comprises a second sensor chip made of silicon and comprising a pixelized main side comprising a plurality of pixels and integrated CMOS electronics electrically connected to the plurality of pixels, and a high voltage main side opposite to the pixelized main side. A first PCB is electrically connected to the integrated CMOS electronics of the first sensor chip and a second PCB electrically connected to the integrated CMOS electronics of the second chip. The first and second sensor chips are superimposed on top of each other with the high voltage main sides of the first and second sensor chips facing each other and with a gap therebetween. The sensor stack also comprises a connector PCB electrically connected to the first and second PCBs of the multiple sensor pairs.

Another aspect of the invention relates to a 3D detector for molecular imaging of an object emitting radiation from radioactive nucleotides. The 3D detector comprises an array or matrix of multiple sensor stacks according to above.

A further aspect of the invention relates to a detector system for molecular imaging of a radionuclide. The detector system comprises a 3D detector according to above and a read-out circuitry connected to the connector PCB and configured to output, for each pixel along an electron track in the 3D detector, a pixel value representative of an energy deposited at the pixel by a Compton recoil electron along the electron track in the 3D detector, wherein the Compton recoil electron is created by a Compton scatter interaction induced by an incident gamma ray in the 3D detector. The detector system also comprises at least one processor, and at least one memory comprising instructions, which when executed by the at least one processor, cause the at least one processor to predict a position of a start of the electron track based on a distribution of the energies deposited at each pixel along the electron track in the 3D detector.

The invention provides sensor stacks to be used as building blocks for 3D detectors in a detector system. Gamma rays incident into the 3D detector generate Compton recoil electrons by Compton scatter interaction. The detector system is able to detect energy deposition caused by a Compton recoil electron along an electron track and to predict the start position of the electron track in the 3D detector. Such as detection of Compton recoil electrons and prediction of the start positions thereof enables the detector system to sort Compton interactions belonging to the same event and prediction of a direction of the incident gamma ray inducing the same event of Compton interactions. This means, together with a high probability for interaction in the semiconductor material, that the detector system will have a higher efficiency and spatial resolution as compared to prior art detector systems for molecular imaging of radionuclides.

### BRIEF DESCRIPTION OF THE DRAWINGS

The embodiments, together with further objects and advantages thereof, may best be understood by referring to the following description taken together with the accompanying drawings, in which:

FIG. 1 schematically illustrates a sensor chip in views from above, from a side and from below.

FIG. 2 schematically illustrates a side view of a sensor pair.

FIG. 3 schematically illustrates multiple sensor pairs superimposed on top of each other.

FIG. 4 schematically illustrates a sensor chip with connected PCB in views from above, from a side and from below according to an embodiment.

FIGS. 5A and 5B schematically illustrates side views of a sensor pair of sensor chips shown in FIG. 4.

FIGS. 6A and 6B schematically illustrates side views of a sensor stack with sensor pairs as shown in FIGS. 5A and 5B.

FIG. 7 schematically illustrates a sensor chip with connected PCB in views from above, from a side and from below according to another embodiment.

FIGS. 8A and 8B schematically illustrates side views of a sensor pair of sensor chips shown in FIG. 7.

FIGS. 9A and 9B schematically illustrates side views of a sensor stack with sensor pairs as shown in FIGS. 8A and 8B.

FIGS. 10A and 10B schematically illustrates sensor chips with connected PCB in views from above, from a side and from below according to a further embodiment.

FIGS. 11A and 11B schematically illustrates side views of a sensor pair of sensor chips shown in FIGS. 10A and 10B.

FIGS. 12A and 12B schematically illustrates side views of a sensor stack with sensor pairs as shown in FIGS. 11A and 11B.

FIGS. 13A and 13B illustrate an embodiment of electrically connecting a PCB to a connector PCB.

FIG. 14 illustrates another embodiment of electrically connecting a PCB to a connector PCB.

FIGS. 15A and 15B illustrate a further embodiment of electrically connecting a PCB to a connector PCB.

FIG. 16 illustrates yet another embodiment of electrically connecting a PCB to a connector PCB.

FIG. 17 illustrates a further embodiment of electrically connecting a PCB to a connector PCB.

FIG. 18 schematically illustrates an embodiment of assembling a 3D detector.

FIG. 19 is an illustration of a monolithic sensor chip according to an embodiment.

FIG. 20 is an illustration of a detector system according to an embodiment.

FIG. 21 schematically illustrates a typical geometry setup for imaging with the 3D detector.

FIG. 22 schematically illustrated part of the process of image reconstruction for the detector system.

FIG. 23 illustrates the number of expected coincident interactions for an activity of 210 MBq for a time stamp resolution of 100 ns without momentum cone limitation (top) and with momentum cone limitation (bottom) from measured Compton recoil electron momentum.

FIG. 24 illustrates the use of momentum of the Compton recoil electron to restrict, to a cone, the volume, in which to look for the next interaction within the chain of interactions generated in the same event.

FIG. 25 illustrates Compton electron tracks simulated with GEANT4.

FIG. 26 is a schematic visualization of the detector geometry used for the simulation.

FIG. 27 schematically illustrates a sensor chip with connected PCB in views from above, from a side and from below according to another embodiment.

FIGS. 28A and 28B schematically illustrates side views of a sensor pair of sensor chips shown in FIG. 4 according to another embodiment.

### DETAILED DESCRIPTION

The present invention generally relates to a sensor stack for molecular imaging of an object emitting radiation from radioactive nucleotides, and a 3D detector system for molecular imaging of radioactive nuclides comprising a plurality of such sensor stacks.

The present invention relates to a 3D detector, also referred to as 3D semiconductor detector or 3D silicon detector herein, and a detector system for molecular imaging of radioactive nuclides, such as in the human body. The 3D detector comprises a block of semiconductor material, in particular silicon, built up from a multitude of sensor chip pairs, with high resolution in space, energy and time. The 3D detector is able to record all incident gamma rays that interact in the silicon volume of the 3D detector, which for practical thicknesses of the semiconductor material will be of the order 50% over a wide energy range. This is many orders of magnitude higher compared to the collimator-based state-of-the art SPECT systems (10⁻⁶), see Table 3.

The detector system is able to record all possible chains of interactions, including one or several Compton scatter interactions, also referred to as Compton effect interactions or simply Compton interactions in the art, i.e., the photon scattering following an interaction with a charged particle, typically an electron, in the silicon material of the 3D detector, followed by absorption by photoelectric effect or escape. This is, together with the high probability for Compton scatter, the reason for the higher efficiency of the detector system of the invention as compared to prior art detector systems, see Table 3. Moreover, given the high resolution for energy and position in the 3D detector, the detector system will be limited in system resolution mainly by the so-called Doppler broadening (Matscheko et al., 1989; Martin et al., 1993; Ordonez et al., 1998), corresponding to the uncertainty in the assumption that the Compton recoil electrons in the Compton scatter interactions are perfectly at rest. This translates to a position resolution at 10 cm distance of 3.8 mm for 140 keV and <1 mm for 511 keV. This means that on top of increased efficiency, the detector system of the invention offers a significant improvement in spatial resolution over state of the art.

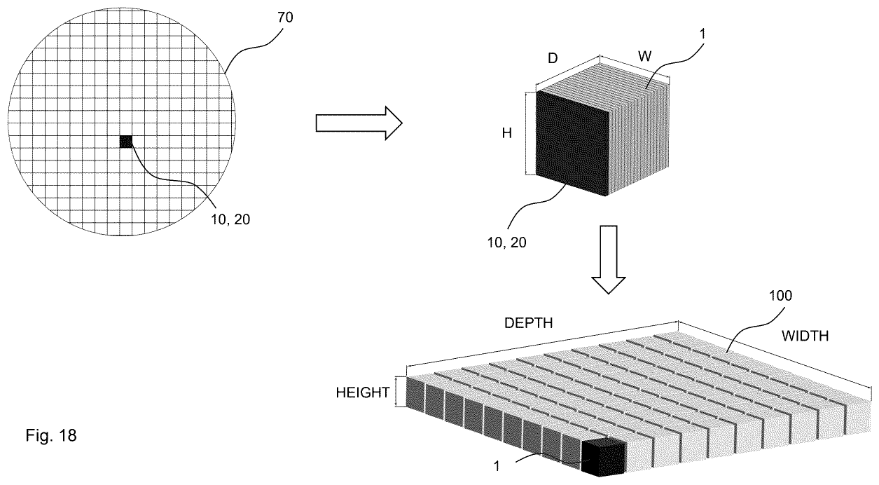

An aspect of the invention relates to a 3D detector 100 for molecular imaging of an object emitting radiation from radioactive nucleotides, see FIG. 18. The 3D detector 100 comprises an array or matrix of multiple sensor stacks 1.

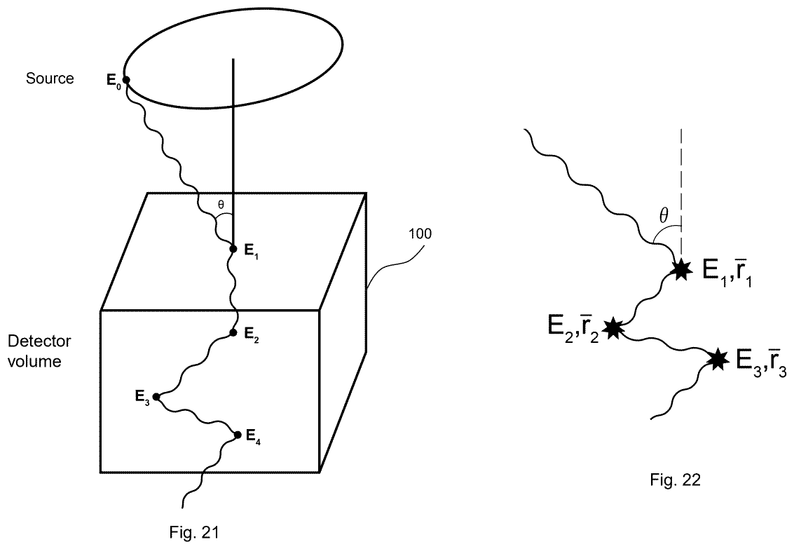

Another aspect of the invention relates to a detector system 1 for molecular imaging of a radionuclide, see FIG. 21. The detector system 1 comprises a 3D detector 100 according to above. The detector system 1 also comprises a read-out circuitry connected to a connector PCB 50 and configured to output, for each pixel 125 along an electron track in the 3D detector 100, a pixel value representative of an energy deposited at the pixel 125 by a Compton recoil electron along the electron track in the 3D detector 100. The Compton recoil electron is created by a Compton scatter interaction induced by an incident gamma ray in the 3D detector 100. The detector system 1 also comprises at least one processor 214 and at least one memory 216 comprising instructions, which when executed by the at least one processor 214, cause the at least one processor 214 to predict a position of a start of the electron track based on a distribution of the energies deposited at each pixel 125 along the electron track in the 3D detector 100.

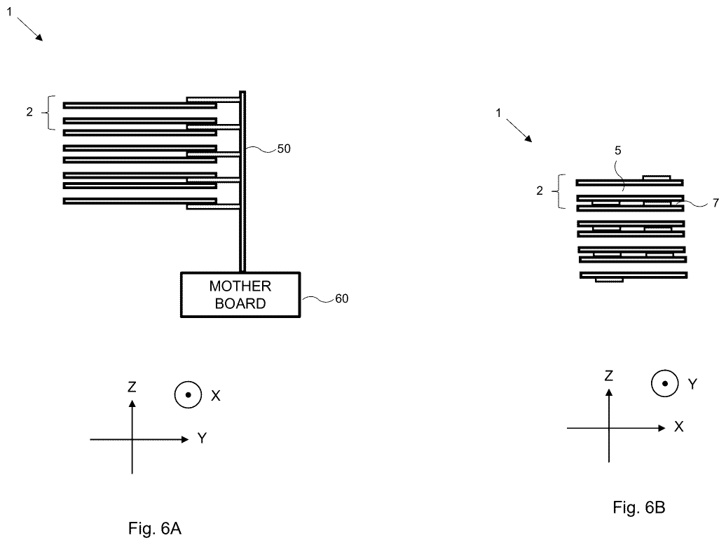

The 3D detector 100 and the detector system 1 of the embodiments register all interactions, including Compton scatter interactions and absorption by photoelectric effect, taking place in the 3D semiconductor detector 100 upon incidence of gamma rays generated by the radionuclides. As schematically shown in FIG. 21, an incident gamma ray may induce a series of such interactions in the detector volume, represented by interactions E₁ to E₄ in the figure. The interactions in the 3D detector 100 induced by a single incident gamma ray are denoted an event herein. Hence, an event comprises one or more such interactions within the detector volume, such as four interactions in FIG. 6. In the art, such an event of interactions induced by a single incident gamma ray is also referred to as a gamma ray track or a track or series of interactions.

In the art of molecular imaging, it is traditionally desired to merely have a single Compton scatter interaction per incident gamma ray followed by absorption by photoelectric effect. Such prior art detector systems, such as in the form of Compton cameras, have therefore been designed to include a scatter detector where the Compton scatter interaction takes place followed by an absorber detector where the scattered photon is absorbed through photoelectric effect. The scatter detector is typically 1-3 mm thick fabricated from a light material so the corresponding probability for an interaction is low. Hence, the design of the scatter detector in such Compton cameras imply that most gamma rays incident onto the scatter detector will not induce any interaction and will thereby not be detected by the Compton camera. Furthermore, since the Compton photon arising in the Compton scatter interaction in the scatter detector can scatter in any direction, only a few of such Compton photons will hit the absorber. Accordingly, the efficiency of such Compton cameras will thereby low, see Table 3.

The 3D detector 100 and the detector system 1 of the embodiments have taken a radically different approach, which significantly improves the efficiency as compared to prior art Compton cameras, or indeed SPECT and PET systems. This is possible by registering all interactions taking place in a comparatively thick detector volume and then sorting the interactions into correct order of interactions per event induced by an incident gamma ray and also sorting the interactions belonging to different events induced by different incident gamma rays. Thus, whereas the prior art solutions have been designed to avoid having multiple Compton scatter interactions in the detector volume as any Compton scatter interaction following the initial Compton scatter interaction causes blurring in such prior art detector solutions, the embodiments make use of all such interactions to improve not only the efficiency but also the spatial resolution and the resolution in energy and time of the detector system 1.

In an embodiment, an energy of the interaction in the 3D detector 100 as used herein means an energy deposited during or at the interaction in the 3D detector 100.

In an embodiment, the at least one processor 214 is configured to reconstruct an image representative of a distribution of the radionucleotide within an object, preferably an animal subject, and more preferably a human subject.

In an embodiment, the silicon material of the 3D detector 100 is produced in so-called wafers 70, see FIG. 18, such as 8-inch diameter wafers 70, that are processed to contain, for instance, about 70 sensor chips 10, 20 with an individual area (H×W) of, for instance 20 mm×20 mm. The wafer 70 may be diced using, for instance, deep reactive ion etching, which gives a well-defined edge, meaning dead area can be kept to a minimum. The sensor chips 10, 20 will be built into sensor pairs 2, which are superimposed onto each other to from sensor stacks 1, also referred to as sensor modules or tiles herein. In such a case, each sensor stack 1 can contain, for instance, around 40 sensor chips 10, 20 with their own power supply and data read-out circuitry. The sensor chips 10, 20 may be attached to each other with a thin layer of glue as part of an automated assembly process. For instance, if the wafers 70 have a thickness of about 0.5 mm, each sensor stack 1 could be in the form of a cube with height (H), width (W) and depth (D) of about 20 mm as an illustrative, but non-limiting, example.

In an embodiment, each sensor stack 1 in the 3D detector 100 is preferably in the form of a hexahedron and in particular a rectangular cuboid.

In an embodiment, the plurality of sensor chips 10, 20 in a sensor stack 1 is attached to each other by gluing.

For connection to the sensor chips 10, 20, printed circuit boards or other electrical connectors or structures 30, 40 may be used to route power and data. Such structures 30, 40 will constitute a “dead volume”. In a preferred embodiment, such structures 30, 40 are only attached to a portion, such as an edge 11, 21, of the sensor chips 10, 20 and can be made in low volume and preferably with a low atomic number, and thus, will have negligible impact on the performance. In general, material (except for silicon material) close to the 3D detector 100 or in the 3D detector 100 should be minimized in volume and atomic number to avoid background from scattered gamma rays. A mechanical structure may be used to keep the sensor stacks 1 together to form the 3D detector 100. Such a mechanical structure can also provide further attachments to power supplies, control systems and data storage. As an illustrative, but non-limiting, example hundred semiconductor stacks 1 could be arranged to form a 3D detector 100 having a depth of ten sensor stacks 1, such as about 200 mm, a width of ten sensor stacks 1, such as about 200 mm, and a height corresponding to the height of a sensor stack 1, such as about 20 mm.

The 3D detector 100 could be arranged on a gantry for rotation around a patient to be imaged. Alternatively, the 3D detector 100 could be designed to surround the patient to detect back to back gamma rays without the need for rotation. As an illustrative, but non-limiting, example the 3D detector 100 could be in the form of a cylinder to detect gammy rays from all direction without the need for rotation.

The building blocks of the 3D detector 100 are, thus, the sensor chips 10, 20 made from a silicon material, such as crystalline silicon, preferably with integrated complementary metal-oxide-semiconductor (CMOS) electronics, for instance each about 0.5 mm thick and with an area of, for instance, 20×20 mm². The sensor chips 10, 20 are, hence, preferably made of crystalline silicon, and preferably crystalline silicon with a resistivity exceeding 5 Ωm. In a preferred embodiment, the sensor chips 10, 20 contain both the sensor and analogue and digital electronics (CMOS electronics) required for signal amplification and processing for all pixels 125 within the sensor chips 10, 20. Using such sensor chips 10, 20 as building blocks, a significant detector volume can be achieved from silicon wafers 70 as indicated in FIG. 18. For instance, a detector volume equivalent of about 1,500 cm³ could be achieved using one hundred 8-inch silicon wafers 70 as starting material for the 3D detector 100. However, much larger detector volumes could be obtained by using more such silicon wafers 70.

A further aspect of the invention relates to a sensor stack 1 for molecular imaging of an object emitting radiation from radioactive nucleotides. The sensor stack 1 comprises multiple sensor pairs 2 superimposed on top of each other. Each sensor pair 2 of the multiple sensor pairs 2 comprises a first sensor chip 10 made of silicon, a first connector 30, a second sensor chip 20 made of silicon and a second connector 40.

The first sensor chip 10 comprises a pixelized main side 12 comprising a plurality of pixels 125 and integrated CMOS electronics electrically connected to the plurality of pixels 125. The first sensor chip 10 also comprises a high voltage (HV) main side 14 opposite to the pixelized main side 12. The first connector 30 is electrically connected to the integrated CMOS electronics of the first sensor chip 10.

The second sensor chip 20 comprises a pixelized main side 22 comprising a plurality of pixels 125 and integrated CMOS electronics electrically connected to the plurality of pixels 125. The second sensor chip 20 also comprises a HV main side 24 opposite to the pixelized main side 22. The second connector 40 is electrically connected to the integrated CMOS electronics of the second sensor chip 20.

The first and second sensor chips 10, 20 are superimposed on top of each other with the HV main sides 14, 24 of the first and second sensor chips 10, 20 facing each other and with a gap 5 therebetween.

The sensor stack 1 also comprises a connector board 50 electrically connected to the first and second connectors 30, 40 of the multiple sensor pairs 2.

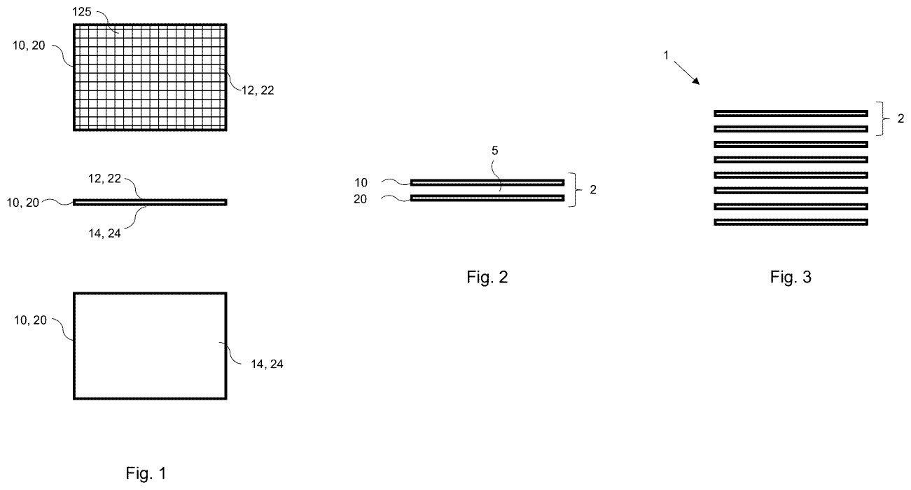

FIG. 1 illustrates an embodiment of a sensor chip 10, 20 as seen from the pixelized main side 12, 22 (top), from a side (middle) and from the HV main side 14, 24 (bottom). The pixelized main side 12, 22, also referred to as frontside herein, is pixelized and thereby comprise a plurality of pixels 125. This pixelized main side 12, 22 also comprises all the CMOS electronics and readout circuitries for the plurality of pixels 125. The opposite main side, i.e., the HV main side 14, 24, also referred to as backside herein, is not pixelized by provides high voltage connections. High voltage as referred to herein typically corresponds to a voltage of a few hundred volts, i.e., is typically selected within an interval of from 1 up to 10 hundred volts.

As is schematically shown in FIG. 1, the first and second sensor chips 10, 20 are preferably two identical sensor chips 10, 20.

FIG. 2 illustrates a sensor pair 2 containing two sensor chips 10, 20 superimposed back-to-back, i.e., with the HV main side 14 of the first sensor chip 10 facing the HV main side 24 of the second sensor chip 20. Having the HV main sides 14, 24 facing each other with a small gap 5 therebetween avoid arcing, i.e., unintended electrical discharge, between the sensor chips 10, 20 in the sensor pair 2.

The multiple sensor pairs 2 are then superimposed or stacked on top of each other as shown in FIG. 3 to form a stack or tile of sensor pairs 2, and thereby of sensor chips 10, 20. The sensor stack 1 is typically in the form of a polygonal prism, preferably a polygonal right prism. In such a case, the joining edges and faces of the prism are perpendicular to the polygonal base faces. The polygonal base is rectangular base, i.e., the sensor chips 10, 20 are preferably rectangular, and may be quadratic.

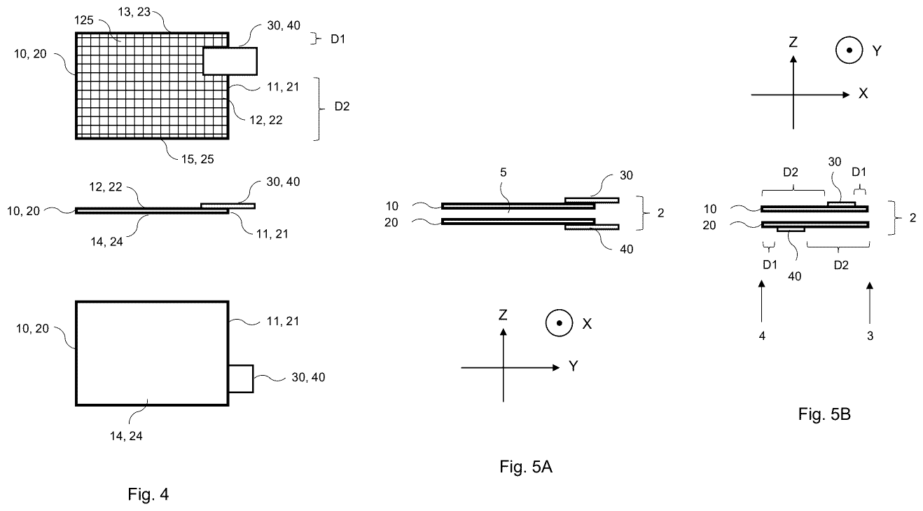

In an embodiment, the first connector 30 is attached to the pixelized main side 12 of the first sensor chip 10 and protrudes beyond an edge 11 of the first sensor chip 10, see FIG. 4. In this embodiment, the second connector 40 is attached to the pixelized main side 22 of the second sensor chip 20 and protrudes beyond an edge 21 of the second sensor chip 20.

In an embodiment, the first connector 30 is laterally offset along the edge 11 of the first sensor chip 10 and the second connector 40 is laterally offset along the edge 21 of the second sensor chip 20. Thus, in a preferred embodiment, the connectors 30, 40 are preferably not centered along the edges 11, 21 of the sensor chips 10, 20 but rather laterally offset, i.e. with a first distance D1 to a first side edge 13, 23 of the first or second sensor chip 10, 20 and a second distance D2 to a second, opposite side edge 15, 25 of the first or second sensor chip 10, 20, wherein the first distance is different than the second distance, i.e., D1≠D2. Such an arrangement of the connectors 30, 40 at the sensor chips 10, 20 allows for a tight stacking of the sensor pairs 2 in the sensor chips as is further described herein in connection with FIGS. 6A and 6B.

FIGS. 5A and 5B are side views of a sensor pair 2 showing the connectors 30, 40 attached to and extending from the pixelized main sides 12, 22 of the sensor chips 10, 20. As is more clearly shown in FIG. 5B, the preferred lateral offset of the connectors 30, 40 means that the first connector 30 is laterally offset along the edge 11 of the first sensor chip 10 with a first distance D1 to a first side edge 3 of the sensor pair 2 and a second distance D2 to a second side edge 4 of the sensor pair 2. In this embodiment, the first distance is different from the second distance (D1≠D2) and the first side edge 3 is opposite to the second side edge 4. Correspondingly, the second connector 40 is laterally offset along the edge 21 of the second sensor chip 20 with the second distance D2 to the first side edge 3 of the sensor pair 2 and the first distance D1 to the second side edge 4 of the sensor pair 4.

FIG. 6A illustrates the connector board 50 electrically connected to the first and second connectors 30, 40 of the multiple sensor pairs 2 and FIG. 6B illustrates the sensor stack 1 from another side view with the connector board 50 removed. As is shown in FIG. 6B, having the connectors 30, 40 of the sensor chips 10, 20 laterally offset as described in the foregoing, allows for a very tight packing of the sensor pairs 2 in the sensor stack 1 with a minimal distance or gap 7 between pixelized main sides 12, 22 of adjacent sensor pairs 2.

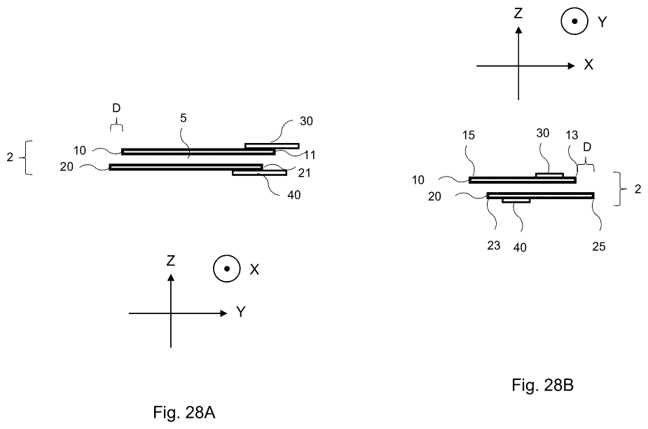

FIGS. 28A and 28B are side views of a sensor pair 2 showing the connectors 30, 40 attached to and extending from the pixelized main sides 12, 22 of the sensor chips 10, 20. In this embodiment, the two sensor chips 10. 20 of the sensor pair 2 are superimposed or piled on top of each other but laterally displaced relative to each other according to different embodiments. In FIG. 28A, the edge 11 of the first sensor chip 10 from which the first connector 30 is protruding is displaced relative to the corresponding edge 21 of the second sensor chip 20. In other words, this edge 11 of the first sensor chip 10 is extending beyond the edge 21 of the second sensor chip 20. FIG. 28B illustrates another embodiment of having the two sensor chips 10, 20 in the sensor pair 1 spatially displaced relative each other. In this embodiment, the second side edge 15 of the first sensor chip 10 extends slightly beyond the first side edge 23 of the second sensor chip 20, and the second side edge 25 of the second sensor chip 20 extends slightly beyond the first side edge 13 of the first sensor chip 10.

In these embodiments, the spatial displacement D between the two sensor chips 10, 20 in a sensor pair 1 could be within the range of sub mm up to one or a few mm.

The overhangs as obtained with such spatial displacements of the first and second sensor chips 10, 20 can be advantageous according to various embodiments. Firstly, the overhangs can be utilized to bonding the connectors 30, 40 to the sensor chips 10, 20. Secondly, the spatial displacement between the sensor chips 10, 20 promote cooling of the HV main sides 14, 24 of the sensor chips 10, 20.

In the above-described embodiment, each sensor chip 10, 20 preferably only has a single connector 30, 40 each that provides the electrical connection or bridge between the pixels 125 in the pixelized main sides 12, 22 of the sensor chips 10, 20 and the connector board 50. In an embodiment, the connectors 30, 40 also handle the electrical connection between the connector board 50 and the HV main sides 14, 24 of the sensor chips 10, 20.

In an embodiment, the first connector 30 is electrically connected to the HV main side 14 of the first sensor chip 10 and the second connector 40 is electrically connected to the HV main side 12 of the second sensor chip 20.

The electrical connection between the connectors 30, 40 and the HV main sides 14, 24 can be achieved according to various embodiments. For instance, the sensor chips 10, 20 may contain channels or through hole through the thickness of the sensor chips 10, 20, in which electrical connections between the PCBs 30, 40 and the HV main sides 14, 24 are running. Such electrical connections could, thus, be in the form of through-hole vias. As an alternatively, electrical connections could be running along the edge 11, 21 of the sensor chip 10, 20 to interconnect the connector 30, 40 and the HV main side 14, 24.

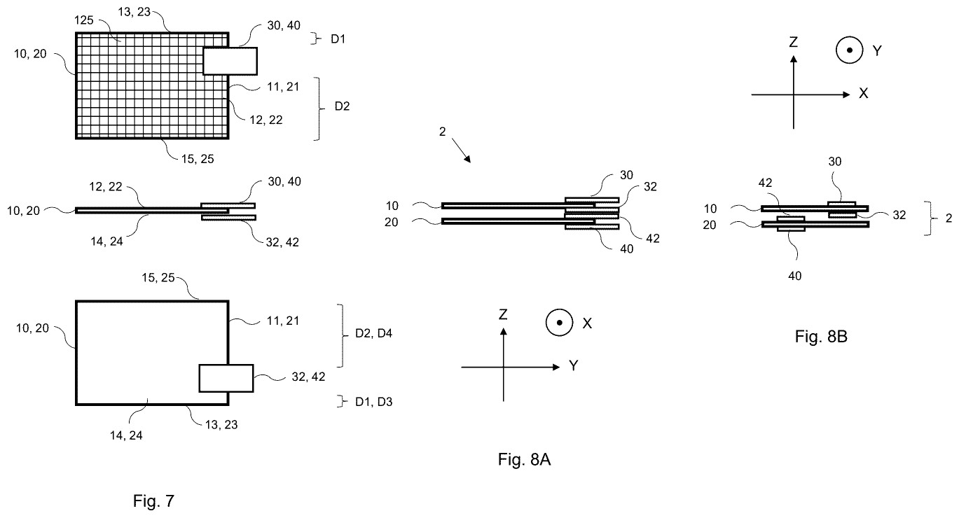

FIG. 7 illustrates another embodiment of the first and second sensor chips 10, 20. In this embodiment, each sensor pair 2 of the multiple sensor pairs 2 comprises a first HV connector 32 connected to the HV main side 14 of the first sensor chip 10 and a second HV connector 42 connected to the HV main side 24 of the second sensor chip 20. In this embodiment, the first HV connector 32 and the second HV connector 42 are electrically connected to the connector PCB 50. In an embodiment, the first HV connector 32 is aligned with the first connector 30 and the second HV connector 42 is aligned with the second PCB 40.

In this embodiment, each sensor chip 10, 20 thereby comprises two connectors 30, 32, 40, 42, one which is electrically connected to the pixelized main side 12, 22, which is also referred to as first or second pixelized connector 30, 40 herein, and the other which is electrically connected to the HV main side 14, 24, i.e., the first or second HV connector 32, 42.

The two connectors 30, 32, 40, 42 per sensor chip 10, 20 are preferably arranged as described in the foregoing, i.e., laterally offset long the edge 11, 21 of the sensor chip 10, 20. This means that the first and second connector 30, 40 (first and second pixelized connector) and the first and second HV connector 32, 42 are preferably laterally offset along the edge 11, 21 of the first or second sensor chip 10, 20 with the first distance D1 to the first side edge 13, 23 of the sensor chip 10, 20 and the second distance D2 to the second side edge 15, 25 of the sensor chip 10, 20 as indicated in FIG. 7.

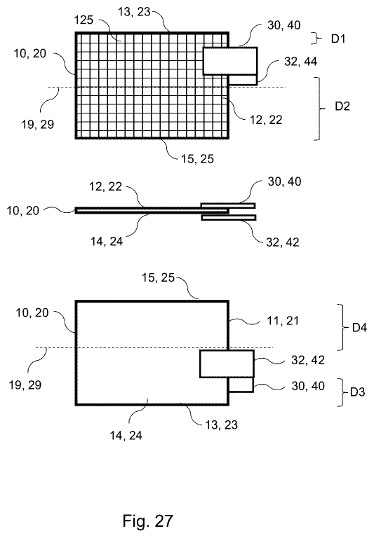

In another embodiment, see FIG. 27, the first and second connector 30, 40 (first and second pixelized connector) are laterally offset along the edge 11, 21 of the first or second sensor chip 10, 20 with the first distance D1 to the first side edge 13, 23 of the sensor chip 10, 20 and the second distance D2 to the second side edge 15, 25 of the sensor chip 10, 20. In this embodiment, the first and second HV connector 32, 42 are laterally offset along the edge 11, 21 of the first or second sensor chip 10, 20 with a third distance D3 to the first side edge 13, 23 of the sensor chip 10, 20 and a fourth distance D4 to the second side edge 15, 25 of the sensor chip 10, 20, wherein D3≠D4.

Thus, in this embodiment, the first and second HV connectors 32, 42 are not necessarily aligned with the first and second connectors 32, 42. This means that the first and second connectors 32, 42 could be laterally offset relative to the side edges 13, 23 of the first and second sensor chips 10, 20 with different distances (D3, D4) as compared to the first and second connectors 30, 40, i.e., D3≠D1 and D4≠D2.

The various distances D1-D4 as mentioned in the foregoing are preferably selected so that the first and second connectors 30, 40 and the first and second HV connectors 32, 34 do not cross the center 19, 29 of the edge 11, 21 of the sensor chip 10, 20. Such an approach allows for a compact arrangement of the sensor pairs 2 in the sensor stack 1 with a minimal distance 7 between adjacent sensor pairs 2 in the sensor stack 1.

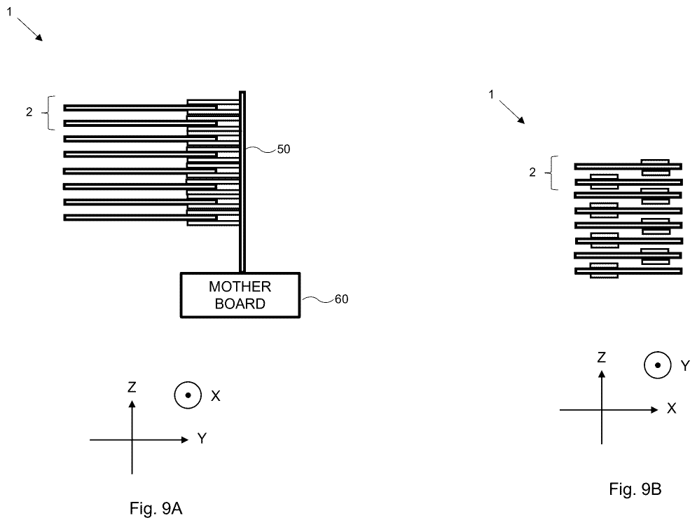

FIGS. 8A and 8B illustrate side views of a sensor pair 2 with first and second sensor chips 10, 20, each comprising two connectors 30, 32, 40, 42. FIGS. 9A and 9B illustrate side views of a sensor stack 1 with such sensor pairs 2.

In this embodiment, the first and second connectors 30, 40 provide the electrical connection between the pixels 125 in the pixelized main sides 12, 22 of the sensor chips 10, 20 and the connector board 50 and the first and second HV connectors 30, 40 correspondingly provide the electrical connection between the HV main sides 14, 24 of the sensor chips 10, 20 and the connector board 50.

In another embodiment, each sensor pair 2 of the multiple sensor pairs 2 comprise a first HV connector 32 connected to the HV main side 14 of the first sensor chip 10. The first HV connector 32 is electrically connected to connector board 50.

In this embodiment, the first HV connector is also electrically connected to the HV main side 24 of the second sensor chip 10.

In an embodiment, the first HV connector 32 is aligned with the first connector 30, see FIG. 10A. The embodiments are, however, not limited thereto. The first HV connector 32 does not necessarily have to be aligned with the first connector 30. In fact, the first HV connector 32 can be arranged anywhere along the edge 11 of the first sensor chip 10 as long as the first HV connector 32 does not overlap the connector 30 when seen from the view as shown in top or bottom of FIG. 10A.

Thus, in this embodiment, the first sensor chip 10 comprises two, preferably aligned, connectors 30, 32 as shown in FIG. 10A, whereas the second sensor chip 20 only comprises one connector 40 electrically connected to the pixelized main side 22 of the second sensor chip 20. The first HV connector 32 then provides the electrical connection between the HV main sides 14, 24 of both the first and second sensor chips 10, 20 in the sensor pair 2.

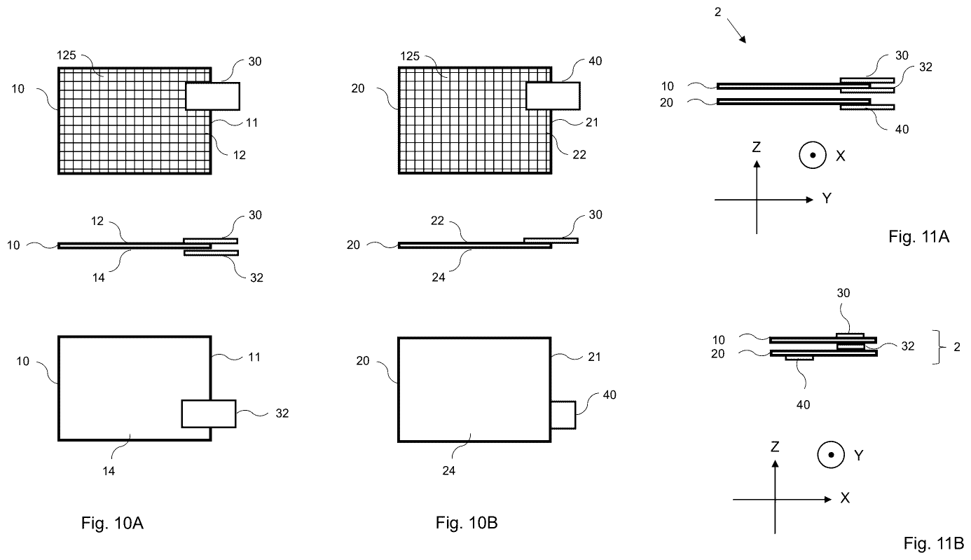

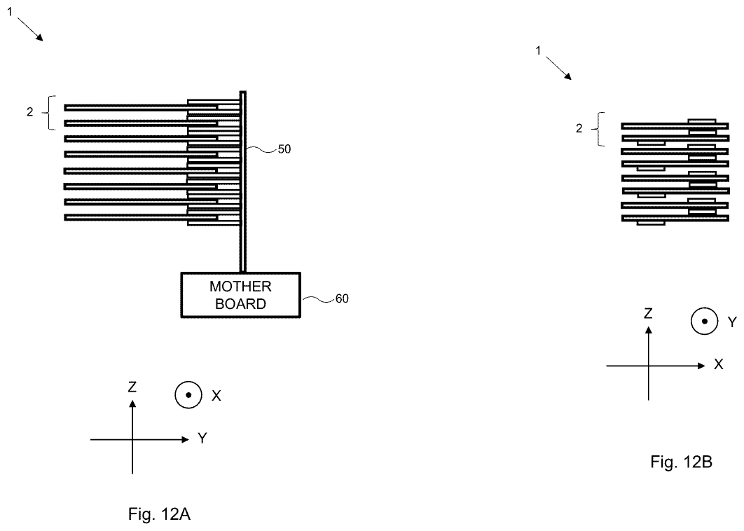

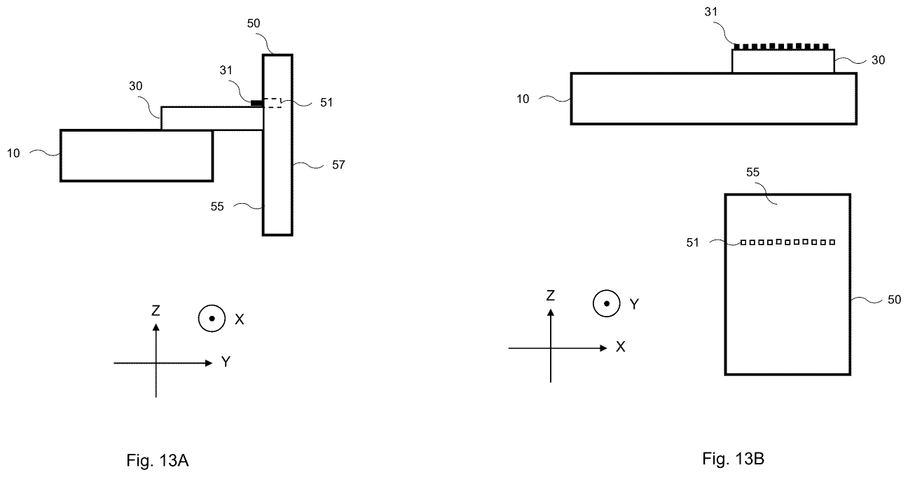

FIGS. 11A and 11B illustrate side views of a sensor pair 2 with first sensor chip 10, 20 comprising two connectors 30, 32 and the second chip 20 comprising one connector 40. FIGS. 12A and 12B illustrate side views of a sensor stack 1 with such sensor pairs 2.

The first and second connectors 30, 40 and the optional first and second HV connectors 32, 42 can be implemented in form of various electrical connectors or connecting structures. These connectors thereby support signals to and from the CMOS electronics, control signals, output signals, bias and ground for depletion of the silicon used as pixels 125.

Illustrative, but non-limiting, examples of such connectors or structures include printed electronics, printed circuit boards (PCBs), chip-on-films (COFs), molded interconnect devices (MIDs), wafer-level fan-outs (WLFOs).

PCBs can be selected from rigid PCBs, flexible PCBs (flex PCBs), rigid-flex PCBs, multilayer PCBs and high-density interconnect (HDI) PCBs.

COFs can be selected from tape carrier packages (TCPs), and anisotropic conductive films (ACFs).

MIDs can be selected from 3D-MIDs, laser direct structuring (LDS) MIDs and injection molded circuitry.

WLFOs can be selected from redistribution layers (RDLs), embedded wafer-level ball grid arrays (eWLBs) and fan-out packaging.

In a preferred embodiment, the first and second connectors 30, 40 are first and second PCBs. Correspondingly, the optional first and second HV connectors 32, 42 are preferably first and second HV PCBs 32, 42.

The connectors 30, 40, 32, 42 can be connected to the sensor chips 10, 20 according to various embodiments including, but not limited to, wire bonding, flip-chip bonding, tape-automated bonding (TAB), soldering, anisotropic conductive film (ACF) bonding, pressure-contact connection, such as zero insertion force (ZIF) or compression connectors, conductive adhesive bonding, and direct laser welding.

The connector board 50 can likewise be implemented in the form of various signal routing connectors or structures, including the ones mentioned above for the connectors 30, 40. In a particular embodiment, the connector board 50 is a connector PCB 50.

The electrical connection between the connectors 30, 32, 40, 42 of the sensor chips 30, 40 in the sensor pairs 2 to the connector board 50 can be achieved according to various embodiments as shown in FIGS. 13 to 17B.

These various embodiments are described in connection with the first and second connectors 30, 40 of the first and second sensor chips 10, 20. However, these embodiments, also apply to the first and second HV connectors 32, 42 if the sensor chips 10, 20 comprise such HV connectors 32, 42.

In the embodiment shown in FIGS. 13A and 13B, the first connector 30 comprises a plurality of connector pins 31. The second connector 40 correspondingly comprises a plurality of connector pins (not shown). In such an embodiment, the connector board 50 comprises, for each first connector 30 and second connector 40, a plurality of through holes or female headers 51 arranged to receive the plurality of connector pins 31.

The connector pins 31 are then preferably connected to a respective main side of the connectors 30, 40 and extend out from this main side. In an embodiment, the connector board 50 comprises, for each first connector 30 and second connector 40 in the sensor stack 1, a plurality of through holes 51, also referred to as through-hole headers in the art. In such a case, the plurality of through holes 51 are arranged and configured to reception of the connector pins 31 of a connector 30, 40. The connector pins 31 can then be inserted into the through holes 51 of the connector board 50 and soldered to the backside 57 of the connector board 50, i.e., the side 57 of the connector board 50 opposite to the side 55 facing the multiple sensor pairs 10, 20 and the connectors 30, 40. In such a case, the backside 57 of the connector board 50 may comprise pads surrounding the through holes 51 and to which the connector pins 31 can be soldered.

In another embodiment, the connector board 50 comprises, for each first connector 30 and second connector 40 in the sensor stack 1, a plurality of female headers 51. Such female headers 51 are in the form of sockets arranged to accept the connector pins 31. In such a case, the connector pins 31 can be inserted into the female headers 51 of the connector board 50 and optionally soldered to the female headers 51.

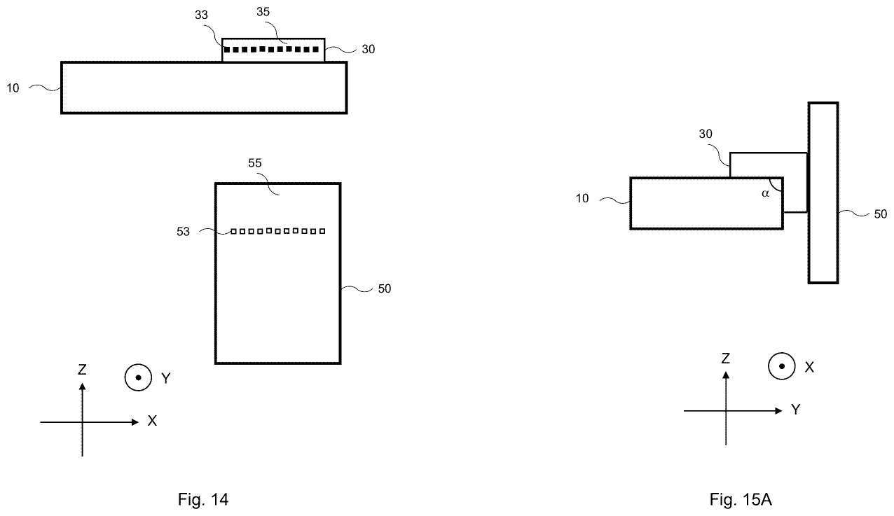

FIG. 14 illustrates another embodiment in which the first connector 30 comprises a connection edge 35 comprising a plurality of vias 33. The second connector 40 correspondingly comprises a connection edge comprising a plurality of vias (not shown). In this embodiment, the connector board 50 comprises, for each first connector 30 and second connector 40, a plurality of matching pads 52 arranged to electrically connect to the plurality of vias 33.

The connectors 30, 40 then comprise a connection edge 33, which is the side or edge 33 of the connectors 33, 43 facing the connection board 50. The plurality of vias 31 are then arranged at this connection edge 33 to electrically interconnect the connectors 30, 40 to the connector board 50. The frontside 55 of the connector board 50, i.e., the side 55 facing the sensor chips 10, 20 and the connectors 30, 40, then comprises matching pads 53 arranged to be electrically connected, such as by soldering, to the vias 33.

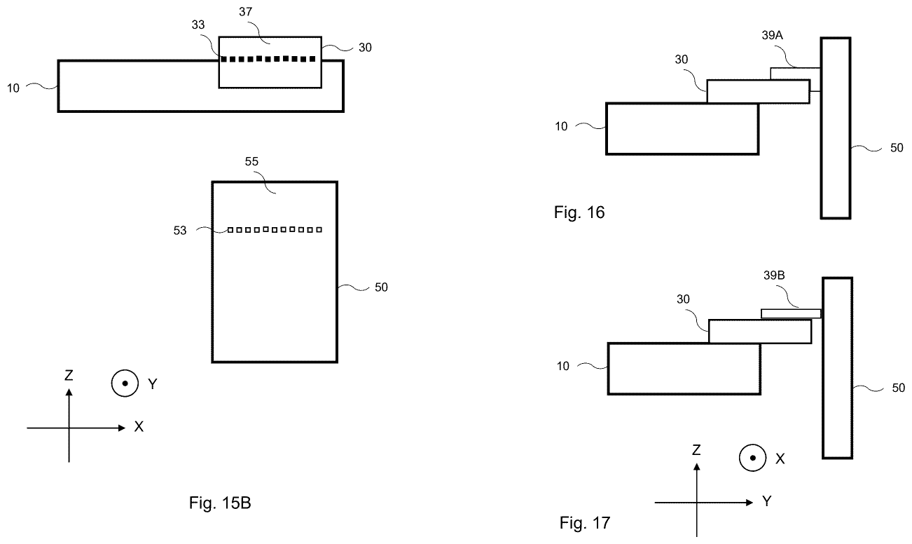

FIGS. 15A and 15B illustrate a further embodiment. In this embodiment, the first connector 30 is a first angled connector 30 comprising a connector side 37 that is angled relative to the pixelized main side 12 and the HV main side 14 of the first sensor chip 10. The connector side 37 comprises a plurality of vias 35. In this embodiment, the second connector 40 is a second angled connector 40 comprising a connector side that is angled relative to the pixelized main side 22 and the HV main side 24 of the second sensor chip 20. The connector side comprises a plurality of vias. The connector board comprises, in this embodiment and for each first PCB 30 and second connector 40, a plurality of matching pads 53 arranged to electrically connect to the plurality of vias 33.

In this embodiment, the connectors 30, 40 are angled at angle ox as schematically shown in FIG. 15A. This angle α is larger than 0° but typically equal to or smaller than 90°, such as being about 90°. The angled connector 30, 40 presents a connector side 37 that faces the frontside 55 of the connector board 50. This connector side 37 comprises the plurality of vias 33 that are then configured to be electrically connected to, such as by soldering, to the matching pads 53 arranged at the frontside 55 of the connector board 50.

FIGS. 16 and 17 illustrate yet other embodiments of providing the electrical connection between the connectors 30, 40 and the connector board 50. In these embodiments, interface boards 39A, 39B are arranged to electrically connect the connectors 30, 40 with the connector board 50.

Thus, in this embodiment, each sensor pair 2 of the multiple sensor pairs 2 comprises a first interface board 39A, 39B electrically connected to the first connector 30 and electrically connected to the connector board 50. The first interface board 39A, 39B is arranged as an electric bridge between the first connector 30 and the connector board 50. Each sensor pair 2 also comprises a second interface board electrically connected to the second connector 40 and electrically connected to the connector board 50. This second interface board is arranged as an electric bridge between the second connector 40 and the connector board 50.

The interface boards 39A, 39B could be angled interface boards 39A as shown in FIG. 16, or planar interface boards 39B as shown in FIG. 17. The angled interface board 39A of FIG. 16 could then be electrically connected to the connector PCB 50 as described in the foregoing in connection with FIGS. 15A and 15B. The planar interface boards 39B of FIG. 17 could be electrically connected to the connector board 50 as described in the foregoing in connection with FIGS. 13A, 13B and 14.

The first sensor chip 10 of a sensor pair 2 is preferably attached to the second sensor chip 20. For instance, the first sensor chip 10 could be attached by adhesive or glue to the second sensor chip 14. In such an embodiment, such adhesive or glue is preferably provided at the HV main sides 14, 24 of the first and second sensor chips 10, 20. These adhesive or glue could be an electrically conducting adhesive or glue since both HV main sides 14, 24 are preferably at the same bias voltage, or an electrically non-conductive adhesive or glue.

In an embodiment, the adhesive or glue comprises spacer particles.

Such spacer particles may be included in the adhesive or glue to control the bond line thickness and uniform spacing between the bonded HV main surfaces 14, 24 of the first and second sensor chips 10, 20 of a sensor pair 2. Spacer particles are typically in the form of microscopic or nanoscopic beads, which can be made of various materials including, but not limited to, glass, polymer materials, ceramic materials, metal or metal alloy, or silica.

In an embodiment, the first sensor chip 10 is attached by adhesive or glue to the second sensor chip 20 at multiple spatially separated attachment points along a circumference of the first and second sensor chips 10, 20. Thus, in a preferred embodiment, the adhesive or glue, preferably the adhesive or glue comprising space particles, is provided at multiple spatially separated attachment points. This further means that no adhesive or glue is provided between the spatially separated attachment points. These non-glued parts of the sensor chips 10, 20 allows for an air-flow in the gap 5 between the two sensor chips 10, 20 of a sensor pair 2. Such an air-flow or air-circulation between the sensor chips 10, 20 allows for an efficient cooling of the sensor chips 10, 20 in the sensor stack 1 during use of the 3D detector 100.

In an embodiment, the sensor stack 1 also comprises a motherboard 60 electrically connected to the connector board 50.

In such an embodiment, the motherboard 60 may be connected to the processor 214 of the detector system 200.

The motherboard 60 is then the main board for the 3D detector 100. The 3D detector 100 may comprise one such motherboard 60 electrically connected to the connector boards 50 of all sensor stacks 1 in the 3D detector 100. Alternatively, each sensor stack 1 could have its own motherboard 60 that is electrically connected to the connector board 50 of that sensor stack 1. It is further possible to have multiple motherboards 60 in the 3D detector 100 and in which one motherboard 60 of the multiple motherboards 60 is electrically connected to the connector boards 50 of a subset of the sensor stacks 1. In other words, two or more sensor stacks 1 may share the same motherboard 50.

The motherboard 60 thereby acts an interface between the connector boards 50 and circuitry of the detector system 200, distributing power to the components of the sensor stack 1 and facilitates data communication between the sensor stack 1 and the processor(s) 214 of the detector system 200.

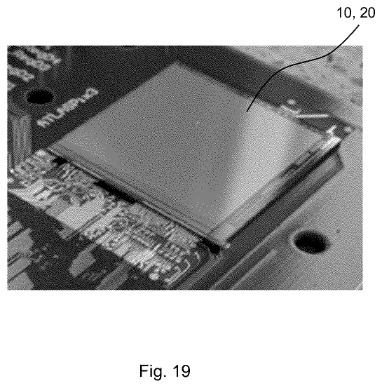

The sensor chips 10, 20 are typically in the form of monolithic sensor chips integrating the CMOS electronics into the sensor chips 10, 20 and thereby creating a single monolithic piece of silicon material. This has advantages in being simpler and cheaper since advanced processes for bonding the CMOS to the sensor chips 10, 20 are not required. FIG. 19 illustrates an embodiment of a monolithic silicon sensor chip designed for the ATLAS experiment at CERN having a size of 20×21 mm with pixels dimensions of 150×50 μm (Peric et al., 2021). Such a monolithic silicon sensor chip could be used as sensor chips 10, 20 with integrated CMOS electronics for the 3D detector 100. However, whereas the ATLAS experiment at CERN requires a count rate per pixel 125 or about 75×10³ kHz, the 3D detector 100 of the embodiments can use a much lower count rate per pixel 125, such as about 1×10⁻³ Hz, implying that the power consumption can be reduced at the same performance. Also, readout strategy will be different since for any time stamp only around ten pixels 125 in a million will be hit during use of the detector system 200. This means that digital functionality does not need to be at the pixel level but a sample and hold structure can be used, where analogue charge is stored and flagged to be read-out and a digitizer can be shared between many pixels 125. The electron-hole pairs created by the Compton recoil electrons will diffuse over several pixels 125, and the resulting distribution of induced charge can be fitted with e.g., a Gaussian distribution. The position of the maximum value will give a sub-pixel spatial resolution (Sundberg et al., 2021) in the plane of the charge collecting electrodes, i.e., pixels 125, down to 1 μm spatial resolution. In the remaining dimension, along the wafer thickness of the sensor chips 10, 20, the width of the distribution can be used to estimate the depth of interaction. For instance, for a 500 μm thick sensor chip 10, 20, a resolution of <100 μm can be achieved. The amount of diffusion can be controlled with the bias voltage of the sensor chips 10, 20. Lower bias voltages will imply a wider charge distribution since the drift time will be longer.

Corradino et al., 2021; Corradino et al., 2022; Corradino et al., 2023; Corradino et al., 2024; De Cilladi et al., 2021; Neubüser et al., 2021; Neubüser et al., 2022; Neubüser et al., 2023a; Neubüser et al., 2023b; and Pancheri et al., 2023 provide information of implementation of monolithic sensor chips 10, 20 that could be used according to the embodiments.

Hence, one way to construct the 3D detector 100 is to use sensor pairs 2 of monolithic sensor chips 10, 20 as building blocks. Integrating the electronics into the sensor chips 10, 20 means that components that are separate today (integrated circuit and sensor) will be merged into one. This implies several practical advantages, including avoiding the need for advanced interconnection techniques. It also means that the power per pixel 125 can be reduced, which is very advantageous since the total number of pixels 125 will be very large for the 3D detector 100. For instance, considering about 5,500 pixels 125 per monolithic sensor chip 10, 20 and assuming about 3,750 monolithic sensor chips 10, 20 in the 3D detector 100, there will in total be around 20 million pixels 125 for the 3D detector 100.

In an embodiment, the plurality of sensor chips 10, 20 comprises CMOS electronics comprising an ASIC comprising analogue to digital converters (ADCs) and the read-out circuitry.

In a particular embodiment, each sensor chip 10, 20 of the multiple sensor pairs 2 is a monolithic sensor chip 10, 20, preferably monolithic silicon sensor chip 102, 20 integrating the CMOS electronics and the plurality of pixels on the monolithic sensor chip 10, 20.

In an embodiment, the sensor chips 10, 20 have a cross section for Compton scattering of more than 40% at 140 keV.

Table 1 below discloses specifications for silicon sensor chips 10, 20 with a total power consumption for the detector system 1 between 150 W and 750 W.

TABLE 1
specification for silicon sensor chips

| Parameter | Specification | |
|---|---|---|
| RMS noise | 360 | eV |
| Power | 10-100 | mW/cm² |
| Shaping time | <1-10 | μs |
| Energy level | 256 | |
| Sensor chip size | 20 × 20 | mm² |
| Pixel size | 400-100,000 | μm² |
| X, Y spatial resolution (RMS) | 1-100 | μm |
| Z spatial resolution (RMS) | <300 | μm |

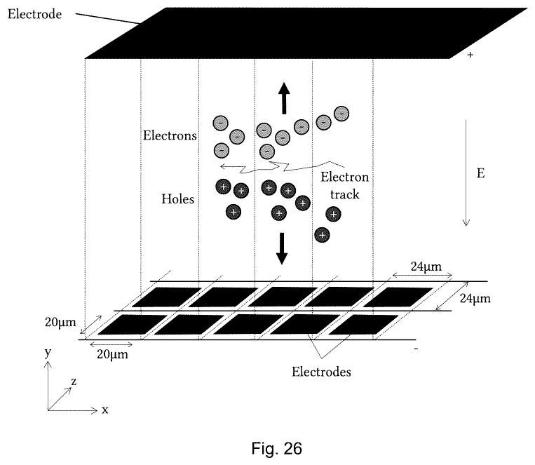

The basic concept of the 3D detector 100 of the detector system 1 is that each incident gamma ray will cause a cascade of interactions starting with an initial Compton scatter, and each of those interactions will be recorded with information of energy, time and position, such as in x, y, z coordinates, of the pixels 125 with signals from the Compton electron tracks induced by the Compton scatter interactions. From the distribution of the pixels 125 in the 3D detector 100 that record interactions, the energy of the Compton recoil electron can be calculated by adding the pixel signals. In more detail, at each Compton scatter interaction the gamma ray (photon) transfers energy to a Compton recoil electron. The Compton recoil electron will travel a short path (“Compton electron track” or simply “electron track”) before it has lost its kinetic energy. The Compton recoil electron will, during this path, excite electron-hole pairs in the silicon material of the 3D detector 100, see FIG. 26. For instance, in the case of silicon, it takes 3.6 eV to excite an electron-hole pair so for a Compton recoil electron with an energy of 20 keV over 5,500 electron-hole pars will be created along the electron track. The electron-hole pairs will be accelerated by the built in electric field in the sensor chips 10, 20 and induce a charge at the pixels (electrodes) 125, which charge is input to the front-end electrodes of the sensor chips 10, 20, i.e., the pixelized main sides 12, 22, as shown in FIG. 26. The summed or integrated charge at the pixels (electrodes) 125 is proportional to the energy of the Compton recoil electron.

The starting point of the Compton electron track can be determined based on a distribution of the energies deposited at each pixel 125 along the electron track in the 3D detector 100. The present disclosure shows how such a distribution of deposited energies can be used to predict the start position of the electron track, for instance based on identifying a center of a charge cloud in the 3D detector 100 or based on the identification of a pixel position associated with the least amount of energy deposition along the electron in the 3D detector 100.

The momentum of the Compton recoil electron can be deduced from the beginning of the Compton electron track, for example with a linear fit. The energy of the incident gamma ray is known since it is determined by the particular radionuclide used. A primary gamma ray can go straight through the 3D detector 100 with no interactions recorded, and this will correspond to a loss in efficiency. However, for all relevant energies, a significant fraction of the incident gamma rays will interact one or more times before escaping the 3D detector 100 or being absorbed in a photoelectric interaction.

The detector system 1 is configured to put the interactions belonging to a same event induced by a single incident gamma ray in the correct order of consecutive interactions and find the first interaction of the event to calculate the direction of the incoming gamma ray, i.e., the angle of incidence θ of the gamma ray, see FIG. 21. The most intuitive way to solve this problem would be to have time stamps precise enough to resolve the order of interactions. This method has been used in space experiments with large separation between sensors (Caputo, 2022) but is not practical for medical imaging. For example, separating two interactions with a distance of 1 cm would require a time resolution of 33 ps (1 cm/c, with c being the speed of light), which is difficult to achieve, and more importantly, would drive to an unrealistic power consumption for the required volume of the 3D detector 100.

Rather, in an embodiment, kinematic constraints can be used to determine the correct order of interactions. Such kinematic constraints will not only facilitate in determining the correct order of the interactions per event but also reject object scatter background. In such an embodiment, time stamps for each interaction can be used together with kinematic constraints to map each interaction to the correct event.

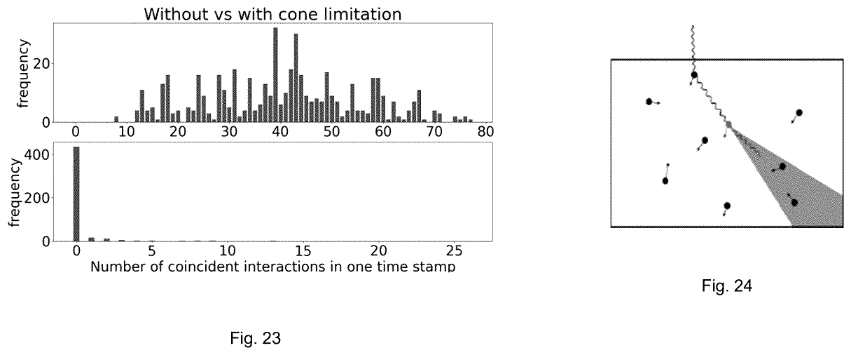

The detector system 1 should make sure that interactions originating from different primary gamma rays are not mixed up but kept as separate events. FIG. 23 shows an example how many coincident interactions are detected for an activity of 210 MBq and time stamp resolution of 100 ns. The figure shows the number of expected coincident interactions without usage of a momentum cone limitation (top) and with a momentum cone limitation (bottom) from the measured Compton recoil electron momentum. Coincident interaction means an interaction requiring kinematic constraints to sort the interactions to the correct event. Hence, zero coincident interactions in one time stamp means that the time stamp resolution was enough to sort interactions into the correct event. If the momentum of the Compton recoil electron in the interaction is determined, this can constrain the volume (“momentum cone limitation”), in which to look for the next interaction as shown in FIG. 24. This volume will be determined by the opening angle of the constrained cone, which is proportional to the uncertainty of the Compton recoil electron momentum. Such an approach will mitigate the problem of mapping interactions with the same time stamp to the correct event as shown in the lower part of FIG. 23.

There are three major reasons to measure the electron track of the Compton recoil electron for momentum estimation. Firstly, increased accuracy of the interaction point. If the start of the Compton electron track cannot be determined, the estimated position of interaction will be less accurate. For lower energies this effect is not significant since the Compton electron track <10 μm. Secondly, less ambiguity in sorting interactions into the correct event and in the correct order. Thirdly, less ambiguity in image reconstruction since the Compton cone angle will be constrained to an arc. This also limits noise propagation.

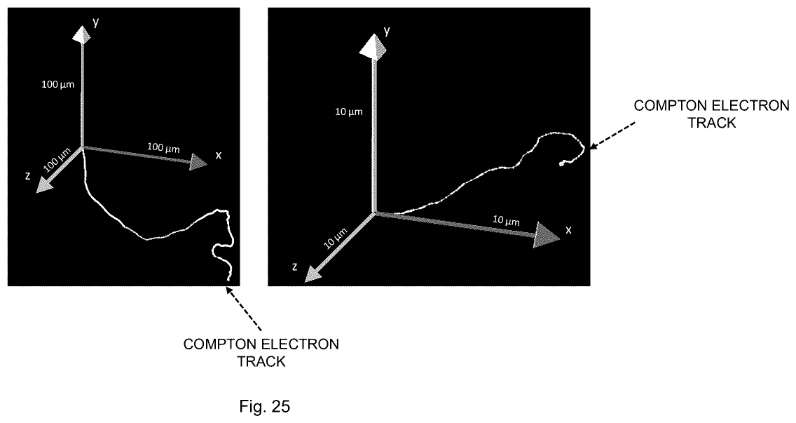

FIG. 25 shows examples of Compton electron tracks for different energies (100 keV to the left and 40 keV to the right) simulated by GEANT4. As can be seen, the Compton electron tracks are not a straight line. A linear fit has been used to the first 10% of the Compton electron track to make sure that the electron momentum is estimated before significant electron scatter. The start versus the end of the Compton electron track can be determined by the straggling effect since more energy is deposited towards the end of the track. Accordingly, a higher charge will be deposited at pixel(s) 125 at the end of the electron track as compared to at the start of the electron track.

For low electron energies it will not be possible to reconstruct the Compton electron track. Fortunately, for those events, since the Compton electron track is very short, the location of the interaction will still be accurate. However, very few pixels 125 will be hit in each time stamp in the 3D detector 100 and most pixels 125 will not have to be read out. A sample and hold strategy can be used where the analogue charge is stored locally in the pixel 125 after amplification and each pixel 125 with a hit will be flagged and digitized in consecutive order. To further suppress noise and lower the minimum threshold for an interaction to be flagged, a condition can be added that at least two adjacent pixels 125 have fired, which will be true for real events but not for random noise.

For low energy Compton recoil electrons the position of the start of the electron track is predicted by identifying a center of a charge cloud in the 3D detector 100. Generally, an incoming gamma ray undergoes Compton scattering in the 3D detector 100 as indicated in FIG. 21. The Compton recoil electrons generated at such Compton interactions (E₁ to E₄ in FIG. 21) travel through the 3D detector 100, depositing energy along their respective electron tracks. The energy is deposited as electron-hole pairs, see FIG. 26, forming a charge cloud. A bias voltage (E in FIG. 26) applied to the pixels 125 causes charge transport of electrons and holes towards electrodes, where they are collected and measured. The charge cloud grows in size due to diffusion when moving towards the electrodes (pixels and common electrode). Due to the diffusion during charge transport together with the preferred small pixel size of the 3D detector 100, charge-sharing between multiple pixels 125 (electrodes) may occur in the scatter detection process. Such charge sharing can be exploited by the present invention in order to achieve sub-pixel resolution of the start position of the electron track.

In an embodiment of the detector system 1, the at least one memory 216 comprises instructions, which when executed by the at least one processor 214, cause the at least one processor 214 to predict the position of the start of the electron track based on a center of a charge cloud in the 3D detector 100 if an estimated energy of the Compton recoil electron is below a first threshold value.

For instance, for low energy Compton electrons, i.e., having an electron below the first threshold, the charge cloud could be estimated by a sphere. In such a case, the center of such a charge cloud corresponds to the start of the electron track.

In an embodiment of the detector system 1, the at least one memory 216 comprises instructions, which when executed by the at least one processor 214, cause the at least one processor 214 to predict the position of the start of the electron track based on a Gaussian fit to the pixel values output by the read-out circuitry if the estimated energy of the Compton recoil electron is below the first threshold value.

In an embodiment of the detector system 1, the at least one memory 216 comprises instructions, which when executed by the at least one processor 214, cause the at least one processor 214 to, if the estimated energy of the Compton recoil electron is below the first threshold value, sum pixel values over a first dimension in the 3D detector 100 to obtain a first one-dimensional projection and sum pixel values over a second dimension in the 3D detector 100 to obtain a second one-dimensional projection. The at least one processor 214 is also caused, in this embodiment, to fit a first Gaussian function to the first one-dimensional projection and fit a second Gaussian function to the second one-dimensional projection. The at least one processor 214 is further caused to determine a first coordinate in the first dimension in the 3D detector 100 based on a mean of the first Gaussian function and determine a second coordinate in the second dimension in the 3D detector 100 based on a mean of the second Gaussian function. In this embodiment, the at least one processor 214 is caused to predict the position of the start of the electron track based on the first coordinate and the second coordinate.

Hence, in this embodiment, the pixel values, such as in mV, are used to estimate the location of the Compton interaction and thereby the start of the electron track. This is accomplished by summing the pixel values over one dimension of the pixels 125 in the sensor chip 10, 20, such as in the x-direction or dimension and the z-direction or dimension in FIG. 26. As a result two one-dimensional projections are obtained. For both dimensions, a Gaussian normal function, such as

$$f ( x ) = a {e}^{- \frac{1}{2} {( \frac{x - b}{c} )}^{2}}$$

is fitted to the projection. Due to charge sharing between pixels 125, the mean b of the fitted Gaussian normal function corresponds to the location of the Compton interaction and thereby the start of the electron track. Thus, the position of the start of the electron track is thereby predicted based on this mean of the fitted Gaussian normal function and can thereby be determined based on an x-coordinate in the x-dimension and a z-coordinate in the z-dimension for the example in FIG. 26 and where the x, y coordinates are obtained from the mean of the fitted Gaussian normal function.

The charge diffusion taking place in the 3D detector 100 can then be exploited for the remaining dimension, i.e., the depth dimension, y-dimension in FIG. 26, by expecting the charge cloud to spread further for interactions away from the Compton recoil electrode. A relation between the standard deviation cₓ and c_{z} of the Gaussian fit and the interaction depth Y can be fitted. The fit is inverted to approximate the interaction depth Yₑ from the width of the Gaussian fit. The average value approximated from x-dimension and z-dimension can then be used to approximate Y₀. The actual detector geometry limited the values, not allowing for y values with Y<0 μm or Y >maximum thickness of the sensor chips 10, 20 (“max”). For values that would be fitted initially outside this range (Y_{e,i}<0 μm or Y_{e,i}>max) based on the fitted function, the average value of the actual depth position of all values higher or lower than the two thresholds can be approximated.

$${Y}_{e} = \{ \begin{matrix}{Y}_{e , i} & 0 \leq {Y}_{e , i} \leq max \\ \{ {\overline{Y}}_{0} \vert {Y}_{e , i} < 0 \} & {Y}_{e , i} < 0 \\ \{ {\overline{Y}}_{0} \vert {Y}_{e , i} > max \} & {Y}_{e , i} > max\end{matrix}$$

Hence, in an embodiment of the detector system 1, the at least one memory 216 comprises instructions, which when executed by the at least one processor 214, cause the at least one processor 214 to, if the estimated energy of the Compton recoil electron is below the first threshold value, estimate a third coordinate in a third dimension in the 3D detector 100 based on a width of the first Gaussian function and a width of the second Gaussian function. The at least one processor 214 is, in this embodiment, also caused to predict the position of the start of the electron track based on the first coordinate, the second coordinate and the third coordinate.

In an embodiment of the detector system 1, the at least one memory 216 comprises instructions, which when executed by the at least one processor 214, cause the at least one processor 214 to, if the estimated energy of the Compton recoil electron is below the first threshold value, compare the value of the third coordinate with a threshold value representing a physical constraint of the sensor chips 10, 20 in the sensor stacks 1 in the third dimension in the 3D detector 100 and determine an updated value of the third coordinate based on the mean of the first Gaussian function and the mean of the second Gaussian function if the value of the third coordinate is below 0 or above the threshold value.

The physical constraint is preferably the maximum thickness of the sensor chips 10, 20.

In an embodiment, the above-mentioned first threshold value is 100 keV. This should, however, merely be seen as an illustrative, but non-limiting, example of a value of the first threshold value. The actual value is dependent, at least partly, on the particular design of the 3D sensor 100.

A longer electron track can be expected for Compton recoil electrons with higher energies. For the relevant electron energies, the energy deposition increases as the electron velocity decreases according to the Bragg peak. Thus, the start of such an electron track can be discriminated from the end of the electron track by the straggling effect meaning that the Compton recoil electron deposits more energy at the end of the electron track as compared to the start of the electron track. Accordingly, the least amount of energy deposition is expected around the initial part of the track. This can be exploited for predicting the position of the start of the electron track for Compton recoil electrons with higher energies, i.e., an energy above a second threshold value.

In an embodiment of the detector system 1, the at least one memory 216 comprises instructions, which when executed by the at least one processor 214, cause the at least one processor 214 to, if the estimated energy of the Compton recoil electron is above the second threshold value, perform linear regression to fit a line to the pixel values. The at least one processor 214 is, in this embodiment, also caused to compare a pixel value at a start of the line with a pixel value at an end of the line and predict the position of the start of the electron track as the one of the start of the line and the end of the line having a pixel value representing a lowest amount of energy deposited at the pixel 125.

In an embodiment of the detector system 1, the at least one memory 216 comprises instructions, which when executed by the at least one processor 214, cause the at least one processor 214 to, if the estimated energy of the Compton recoil electron is above the second threshold value, sum, for each pixel 125 having a pixel value above a minimum threshold value, pixel values within a pixel area of N×M pixels 125 centered at the pixel 125, and predict the position of the start of the electron track based on a position of the pixel 125 having the smallest sum.

In a particular embodiment of the detector system 1, the at least one memory 216 comprises instructions, which when executed by the at least one processor 214, cause the at least one processor to 214, if the estimated energy of the Compton recoil electron is above the second threshold value, set each pixel value below the minimum threshold value to zero and sum, for each pixel 125 having a non-zero pixel value, pixel values within the pixel area of N×M pixels 125 centered at the pixel 125.

In a particular embodiment, N=2×k+1, M=2×h+1 and k, h are each a positive integer equal to or larger than one. In a preferred embodiment, k=h.

The readout from the read-out circuitry is, in an embodiment, cleaned from noise by setting a minimum threshold, such as at 5 mV, and setting everything below the threshold to zero. Thus, pixels having a pixel value below this minimum threshold, such as below 5 mV, have their pixel values set to zero. 5 mV should merely be seen as an illustrative, but non-limiting, example of such a minimum threshold and the embodiments are not limited thereto.

For each remaining non-zero pixel, the sum of the output in a square of, for instance, 5 by 5 pixels 125 centered around a considered pixel 125 is computed, and the center of the pixel 125 with the smallest sum is approximated as the interaction position. Thus, following resetting pixel values below the minimum threshold value to zero, non-zero pixels 125 are identified and pixel values within a pixel area centered at each non-zero pixel 125 are summed. Accordingly, a respective such sum is obtained for each non-zero pixel 125. The actual size of the pixel area can be selected in an optimization process. The pixel area could be a rectangular pixel area if N+M, but is preferably a quadratic pixel area, i.e., a square, and N=M. The pixel area preferably comprises an odd number of pixels 125 in each dimension so that it can be centered at a given non-zero pixel 125.

In an embodiment, the above-mentioned second threshold value is 100 keV. This should, however, merely be seen as an illustrative, but non-limiting, example of a value of the second threshold value. The actual value is dependent, at least partly, on the particular design of the 3D sensor 100.

In a particular embodiment, the first threshold value is equal to the second threshold value.

As is schematically shown in FIG. 16, each semiconductor chip 10, 20 of the 3D detector 100 preferably comprises a plurality of electrodes at the pixelized main side 12, 22 and at least one counter electrode at the HV voltage main side 14, 24. A bias voltage (E in FIG. 26) is then applied between each electrode of the plurality of electrodes and a counter electrode of the at least one counter electrode.

The sensor chips 10, 20 comprise a plurality of pixels 125 in the pixelized main surface 12, 22 and where each such pixel 125 comprises an electrode. For instance, a pixel 125 with a pixel size of 24 μm×24 μm could comprise an electrode of 20 μm×20 μm. The sensor chips 10, 20 also comprise one or more counter electrodes at the HV main side 14, 24 for the electrodes. In an embodiment, the sensor chips 10, 20 comprises a single counter electrode that is shared by all the electrodes in the sensor chips 10, 20. In another embodiment, the sensor chips 10, 20 comprises multiple counter electrodes. In such an embodiment, the bias voltage is applied between a first set of electrodes and a first counter electrode, between a second set of electrodes and a second counter electrode, and so on.

In a volume of silicon, the percentage of different types of interactions caused by incident gamma rays is shown in Table 2. A large fraction of the incident gamma rays can be reconstructed and used for image reconstruction by the detector system 1. Since all interactions are detectable, there is no penalty in having a thick 3D detector 100 with multiple Compton scatterings. Moreover, due to the solid block of the 3D detector 100, the probability is higher for scattered gamma rays to interact a second time. Altogether, this leads to a significant efficiency gain for the 3D detector 100 over both state-of-the-art collimator-based SPECT but also Compton camera prototypes. In fact, the detector system 1 of the embodiments can even outperform PET both in efficiency and spatial resolution.

TABLE 2
GEANT4 simulation

| Type of | | | | |
|---|---|---|---|---|
| interaction | 140 keV | 511 keV | 700 keV | Comment |
| 1 Compton scatter | 19% | 23% | 23% | Recoil electron momentum required to |
| and escape | | | | estimate direction of incident gamma ray, |
| | | | | reduced spatial resolution since only one |
| | | | | Compton interaction is detected |
| >1 Compton | 23% | 33% | 31% | Recoil electron momentum will constrain the |
| scatter and | | | | event circle to a cone but is not required to |
| escape | | | | estimate direction of incident gamma ray |
| ≥1 Compton | 39% | 14% | 10% | Recoil electron momentum will constrain the |
| scatter and photo | | | | event circle to a cone but is not required to |
| absorption | | | | estimate direction of incident gamma ray |
| 1 photo | 5% | 0.2% | 0.1% | Direction of incident gamma ray cannot be |
| absorption | | | | determined |
| No scatter or | 12% | 30% | 35% | Direction of incident gamma ray cannot be |
| photo absorption | | | | determined |

Table 2 illustrates GEANT4 simulation of three different energies of primary gamma rays (140, 511 and 700 keV) incident on 6 cm silicon at the center of a 20×20 cm² area.

In an embodiment, the event induced by the incident gamma ray comprises at least one Compton scatter interaction in the 3D detector 100 followed by absorption by photoelectric effect in the 3D detector 100 or escape. In a particular embodiment, the event induced by the incident gamma ray comprises multiple, i.e., at least two, Compton scatter interactions in the 3D semiconductor detector 100, see for instance FIG. 21, followed by absorption by photoelectric effect in the 3D detector 100 or escape.

In an embodiment, the time information in the signals output by the read-out circuitry can be used to group interactions. In such an embodiment, the at least one memory 216 comprises instructions, which when executed by the at least one processor 214, cause the at least one processor 214 to group interactions having a respective time, represented by the signals output by the read-out circuitry, within a defined time interval.

The at least one processor 214 is, in this embodiment, also caused to predict, based on the signals output by the read-out circuitry, the interactions in the 3D detector 100 belonging to the same event included by the gamma ray among the grouped interactions.

Thus, the time stamps or other time information of the interactions in the 3D detector 100 can be used to group interactions having a respective time stamp or time within a defined time interval. For instance, the grouping could involve the interactions having a time falling within the time window or interval of from t₁ up to t₂, i.e., those interactions Ek having a time tₖ among n interactions (k=1 . . . n) for which tₖ ∈[t₁, t₂] or t₁≤tₖ≤t₂, wherein t₁<t₂. Alternatively, the time interval could be defined as t±Δt, i.e., cantered around some defined time point t.

In this embodiment, prediction of the interactions belonging to the same event induced by the incident gamma ray is limited to grouped interactions, i.e., to a subset of all detected interactions. This significantly simplifies the sorting of interactions into different events and further sorting the interactions within one event in correct order.

As mentioned in the foregoing, the interactions in the 3D detector 100 comprise at least one, typically multiple, Compton scatter interactions. In such a case, the read-out circuitry is preferably configured to output, for each Compton scatter interaction induced by the incident gamma ray in the 3D detector 100, the signal representative of the time, the position of creation of a Compton recoil electron and the energy of the Compton recoil electron induced by the Compton scatter interaction in the 3D detector 100.

Thus, in this embodiment, at each Compton scatter interaction, the scattered gamma ray (photon) transfers part of its energy to a Compton recoil electron. The timing and position of such an energy transfer, i.e., creation of a Compton recoil electron, can then be detected as the time and position of the Compton scatter interaction in the 3D detector 100. The position of such energy transfer or creation of the Compton recoil electron corresponds to the above-mentioned position of the start of the electron track.

Such a detection of the Compton recoil electron is possible since the Compton recoil electron will travel a short path, referred to as Compton electron track or simply electron track in the art, before losing its kinetic energy and will, during this path, excite electron-hole pairs, which can be detected at the pixels 125.

In an embodiment of the detector system 1, the at least one memory 216 comprises instructions, which when executed by the at least one processor 214, cause the at least one processor 214 to sort the predicted interactions in the 3D detector 100 belonging to the same event in an order of consecutive interactions based on the signals output by the read-out circuitry.

Hence, the information of the time, position and energy of the interactions as represented by the signals output by the read-out circuitry is used to sort or order the interactions belonging to the same event in correct, i.e., consecutive, order starting from the first or initial interaction and ending with the last interaction in the 3D detector 100 for the given event.

In an embodiment of the detector system 1, the at least one memory 216 comprises instructions, which when executed by the at least one processor 14, cause the at least one processor 214 to predict an initial interaction of the same event induced by the incident gamma ray in the 3D detector 100 based on the energies in the signals output by the read-out circuitry.

As mentioned above, the Compton recoil electron created in the Compton scatter interaction induces at least one electron-pair along an electron track in the 3D detector 100. In such a case, the detector system 1 preferably comprises a charge circuitry configured to estimate the energy of the Compton recoil electron based on charges induced by the at least one electron-hole pair along the electron track.

In an embodiment, the charge circuitry is configured to estimate the energy of the Compton recoil electron by summing or integrating the charges detected by pixels 125 in the 3D detector 100 along the electron track of the Compton recoil electron.

The estimated energies of Compton recoil electrons can be used to sort interactions and predict the interactions belonging to the same event induced by a given incident gamma ray. For instance, the estimated energies can be used to impose kinematic constraints to reject interactions unlikely to belong to the same event and/or be used in in maximum likelihood estimations to determine the direction of the incident gamma ray.

In an embodiment of the detector system 1, the at least one memory 216 comprises instructions, which when executed by the at least one processor 214, cause the at least one processor 214 to predict, based on the signals output by the read-out circuitry, the interactions in the 3D detector 100 belonging to the same event induced by the incident gamma ray in the 3D detector 100 by imposing kinematic constraints on the Compton scattered gamma ray.

In a particular embodiment, the at least one memory 216 comprises instructions, which when executed by the at least one processor 214, cause the at least one processor 214 to estimate a momentum of a Compton recoil electron based on the pixel values output by the read-out circuitry. The at least one processor 214 is also caused to calculate a kinematic constraint for the Compton scatter interaction, i.e., on the Compton scattered gamma ray, based on the estimated momentum of the Compton recoil electron.

In an embodiment of the detector system 1, the at least one memory 216 comprises instructions, which when executed by the at least one processor 214, cause the at least one processor 214 to estimate the momentum of the Compton recoil electron by a linear fit to a first part of the electron track in the 3D detector 100.

For instance, a linear fit could be used to the first part of the electron track of the Compton recoil electron to facilitate estimation of the momentum of the Compton recoil electron before electron scatter along the electron track. This first part of the electron track could, for instance, correspond to a first predefined percentage of the electron track, such as first 25%, first 20%, first 15%, first 10% or first 5% of the electron track.

In an embodiment of the detector system 1, the at least one memory 216 comprises instructions, which when executed by the at least one processor 214, cause the at least one processor 214 to calculate an opening angle of a constrained cone based on the estimated momentum of the Compton recoil electron. In such an embodiment, the constrained cone restricts the volume in the 3D detector 100, within which a next interaction belonging to the same event induced by the incident gamma ray is allowed to take place.

FIG. 24 illustrates such an approach, in which a constrained cone has been added at the second Compton scatter interaction of an event. The constrained cone thereby limits the volume in the 3D detector 100 so that a next interaction of the same event occurs within the limited volume. In this illustrative example, the number of potential interactions is, by usage of the constrained cone, reduced from eight interactions down to two interactions.

The opening angle of the constrained cone is dependent on the estimated momentum of the Compton recoil electron. In a particular embodiment, the opening angle of the constrained cone is proportional to an uncertainty of the estimated momentum of the Compton recoil electron.

In an embodiment of the detector system 1, the at least one memory 216 comprises instructions, which when executed by the at least one processor 214, cause the at least one processor 214 to estimate, the direction of the incident gamma ray by a maximum likelihood estimation based on the signals output by the read-out circuitry.

Thus, the incident direction of the gamma ray θ in FIGS. 21 and 22, also referred to as angle of incidence of the gamma ray, is estimated by a maximum likelihood estimation in this embodiment.

In a particular embodiment of the detector system 1, the at least one memory 216 comprises instructions, which when executed by the at least one processor 14, cause the at least one processor 214 to estimate the direction of the incident gamma ray by maximizing [symbol] (θ)=P(E₁, r̅₁|θ₁, E₀)×P(E₂, r̅₂|θ₂, E₁, r̅₁)× . . . ×P(Eₙ, r̅ₙ|θₙ, Eₙ₋₁, r̅ₙ₋₁), wherein Eₖ, r̅ₖ, θₖ represent energy, position and incident angle of interaction number k, k=1 . . . n and n represents a last interaction of the same event, and E₀ represents an energy of the incident gamma ray.

The energy of the incident gamma ray E₀ is known and is defined based on the particular radionuclides used. The energies Eₖ can be determined as described in the foregoing for estimation of the energy of Compton recoil electrons based on integration of detected charges along the electron tracks or by deposited energy or charge in the case of absorption by photoelectric effect.

The uncertainty in the direction θ is

$${σ}_{θ} \approx \sqrt{\frac{1}{I ( θ )}} ,$$

wherein

$$I ( θ ) = - E [ \frac{{\partial }^{2}}{\partial {θ}^{2}} ln ℒ ( θ ) ] .$$

The embodiments of the invention are, however, not limited to the above presented examples of interaction sequence sorting methods but can also be used with other such methods including, but not limited to, a simple comparison method, a Compton edge test, a deterministic method, minimum square difference, a three Compton method, a physics based probabilistic method, a maximum likelihood method and neural networks.

A simple comparison method can be used for an event with two interactions. It is based on looking for the interaction that deposits more energy in the 3D detector 100. Knowing the initial energy of the incident gamma ray, if such energy is above 400-500 keV, the incident gamma ray will more likely deposit more energy at the first interaction rather than the second interaction and vice versa if the initial energy is below such threshold (Lee et al., 2021).

A Compton edge test can be used for an event with two interactions or three or more interactions to discard possible permutations. It is based on the fact that there is a maximum energy that can be deposited via Compton interaction, so if one interaction deposits more energy than the threshold, it means that such an interaction is a photoabsorption and as such should be the last of the interaction for the event (Lee et al., 2021).

A deterministic method is mainly used for an event with two interactions and computes the probability for each sequence of interactions based on the Klein-Nishina formula and chooses the sequence of interactions with highest probability (Lee et al., 2021).

Minimum square difference can be used for events with at least three interactions. It is based on computing a figure of merit (FOM) based on redundant geometrical and energetic information on the same angle of scattering, and repeating such calculation 3 by 3 interactions summing all the FOM. The smallest FOM indicate the sequence of interactions that is most likely to be correct (Lee et al., 2021).

A three Compton method can be used for events with at least three interactions. It is based on the Klein-Nishina formula (Lee et al., 2021, Kroeger et al., 2002).

A physics based probabilistic method can be used for events with two or more interactions. This method keeps into account all the physical phenomena (Klein-Nishina formula, Lambert-Beer law, etc.) that a certain photon undergoes in order to generate a specific combination among the possible interactions for that event.

For each permutation the total probability is calculated and the one with the highest probability is selected as correct one (Yoneda et al., 2023, Tashenov and Gerl 2010).

A maximum likelihood method can be used for events with two or more interactions. It is somewhat based on the same physics as physics based probabilistic methods but it extends it further trying to estimate with more precision the incident angle of the gamma ray that maximizes the likelihood function (Sundberg et al., 2022).

Neural networks can be used to reconstruct the interaction sequence (Takashima et al., 2022).

In an embodiment of the detector system 1, the read-out circuitry is configured to output, for each interaction induced by an incident gamma ray in the 3D detector 100, a signal representative of a time, a position and an energy of the interaction in the 3D detector 100. The at least one memory 216 comprises instructions, which when executed by the at least one processor 214, cause the at least one processor 214 to predict, based on the pixel output by the read-out circuitry, the interactions in the 3D detector 100 belonging to a same event induced by the incident gamma ray. The at least one processor 214 is also caused to estimate, based on the predicted interactions in the 3D detector 100 belonging to the same event, a direction of the incident gamma ray inducing the same event and reconstruct an image based on the estimated directions of incident gamma rays.

The image reconstruction is basically a two-step process where the first step estimates the primary interaction position and direction of incidence of the gamma rays, and the second step reconstructs an image from these events. The first of these steps includes separating background events from events induced by incident gamma rays originating from the radionuclides, separating interactions belonging to different events from each other and sorting the different interactions into the correct order. Once this is done, the location of incidence of the gamma rays should coincide with the location of the first interaction and the recovered scattered gamma ray trajectory is used to estimate the direction of incidence. As discussed in the foregoing, various techniques and algorithms can be used in this first step including, but not limited to, kinematical fitting and likelihood-based methods. Alternatively, or in addition, machine learning can be applied to the first step, to recover the photon incidence vector. For this application, boosted decision tree models have demonstrated success for Compton camera imaging in the past (Kozani & Magiera, 2022).

The second step of the image reconstruction for the detector system 1 could be based on various reconstruction algorithms including, but not limited to filtered back projection (Maxim, 2014), direct inversion (Maxim et al., 2009), iterative methods (Wilderman et al., 1998) and deep learning (Daniel et al., 2022; Yao et al., 2022). Machine learning methods, in particular deep-learning-based, can be applied to the second step, to enhance the image reconstruction from a dataset of estimated incidence vectors. In an embodiment, a conventional image reconstruction algorithm, such as filtered back projection, is first applied and then a neural network is used to enhance the resulting image. By training this neural network on pairs of noiseless ground truth images and simulated reconstructions from noisy data, the network is learnt to invert the blurring caused by the imaging system and reduce image noise, thereby improving the resulting image quality (Daniel et al., 2022; Yao et al., 2022). It is also possible to use a single machine-learning-based method that combines these two steps of image reconstruction. An alternative is to use back projections in the image reconstructions as a starting point for maximum likelihood iterative methods.

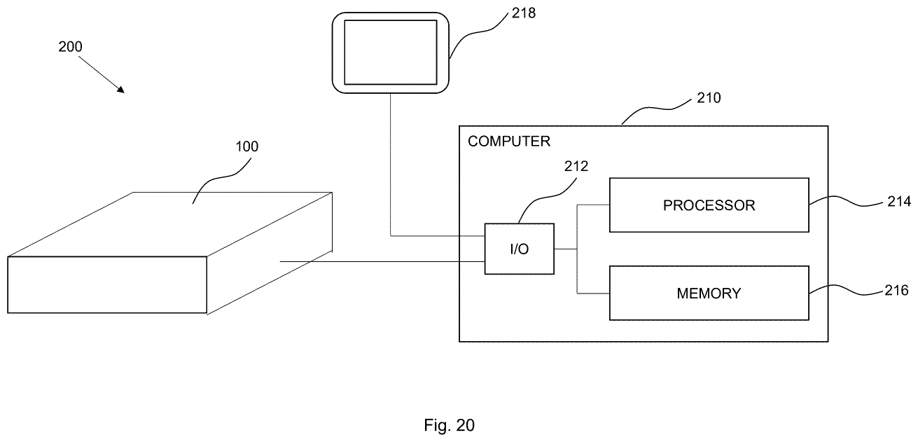

FIG. 20 is a schematic illustration of a detector system 1 according to an embodiment. The detector system 1 as shown in the figure comprises the 3D 2detector 100 and a computer 210 comprising the at least one processor 214 and the at least one memory 216. The computer 210 in FIG. 20 has been shown with a single memory 216. The embodiments are, however, not limited thereto. In clear contrast, the computer 210 could comprise or be, wirelessly or with wire, connected to multiple memories 216, such as a memory system of multiple memories 216. The computer 210 as shown in FIG. 20 also comprises a processor 214. The embodiments are, however, not limited thereto. In clear contrast, the computer 210 could comprise multiple processors 214. The computer 210 further comprises a general input and output (I/O) unit 122 configured to communicate with external devices, such as the 3D detector 100 and a display screen 218. The I/O unit 212 could represent a transmitter and receiver, or transceiver, configured to conduct wireless communication. Alternatively, or in addition, the I/O unit 212 could be configured to conduct wired communication and may then, for instance, comprise one or more input and/or output ports. The I/O unit 212 is in particular connected to the motherboard(s) 60 of the sensor stacks 1 in the 3D detector 100.

The term processor 214 should be interpreted in a general sense as any circuitry, system or device capable of executing program code or computer program instructions to perform a particular processing, determining or computing task. The processor 214 does not have to be dedicated to only execute the above-described steps, functions, procedure and/or blocks, but may also execute other tasks.

In an embodiment, the detector system 1 and 3D detector 100 measures, per interaction in the 3D detector 100, the induced Compton recoil electron track. The scattering of the Compton recoil electron along the electron track gives rise to electron-hole pairs inducing a signal (charge) that can be detected at the pixels 125 of the 3D detector 100. The detected signal is measured and digitized and stored in the memory of the CMOS electronics, preferably at the sensor chips 10, 20 in the case of a monolithic semiconductor sensor chips 10, 20. Each such Compton recoil electron can give rise to a detectable signal at one or a plurality of pixels 125 depending on the energy of the Compton recoil electron and the position of interaction in the 3D sensor 120. This hit map of pixel signals is used to estimate the position, such as r̅=(x, y, z), of the interaction of the gamma ray, i.e., the start of the electron track. Furthermore, the detector system 1 and 3D detector 100 estimates the time t of the interaction and the energy E that the gamma ray lost in the interaction, which energy corresponds to the kinetic energy gained by the Compton recoil electron, which corresponds to the number of electron-hole pairs induced by the Compton recoil electron along its electron track. The incident gamma ray then interacts n times in the 3D semiconductor 100 before leaving the 3D detector 100, i.e., escape, or before being fully absorbed by photoelectric effect.

The detector system 1 thereby estimates the time, location and energy for all detected interactions k, i.e., (tₖ, r̅ₖ, Eₖ)=(tₖ, xₖ, yₖ, z_{K}, Eₖ), The energy of the incident gamma ray, E₀, is known since it is the result of the nuclear decay of the radionuclide, such as 140 keV for technetium-99m (^{99m}Tc) or 511 keV for positron annihilation.

The signals (tₖ, r̅ₖ, Eₖ) obtained from all interactions are used by the detector system 1 to determine the correct order of the interactions, estimate the direction of the incident gamma ray at the first direction for the event and use the direction of the incident gamma ray to reconstruct the image of the distribution of radionuclides in an object, such as body a human subject.

The angular resolution for the detector system 1 is determined by the energy resolution and the spatial resolution at the component level. The energy resolution is dependent on the scattering angle and fundamentally limited by the so called “Doppler broadening”, which is caused by the fact that the Compton recoil electron is not perfectly at rest and not free when hit by the incident gamma ray. The uncertainty in scattered gamma ray energy due to Doppler broadening was estimated by Matscheko et al. 1989 and the impact on Compton angular resolution from energy resolution in general was described by Martin et al. 1993. The impact from spatial resolution of detector was determined by Ordonez et al. 1998. A similar result is obtained for the 3D semiconductor detector using error propagation.

Table 3 summaries performance for state-of-the art SPECT and Compton cameras with the performance of an embodiment of the detector system 1.

TABLE 3
performance data

| | Spatial resolution at 10 | Relative dose | |
|---|---|---|---|
| Detector system | cm distance | efficiency | Comment |
| Collimator SPECT Nal- | 10-20 mm | 1 × 10⁻⁶ | Most common SPECT |
| scintillator | | | system |
| Collimator SPECT | 6-12 mm | 5 × 10⁻⁶ | SPECT system with |
| CdZnTe detector | | | higher performing |
| | | | detector |
| Compton camera | 1-20 mm | 1 × 10⁻³-1 × 10⁻⁶ | High resolution and |
| | | | high efficiency only for |
| | | | energies >500 keV |
| 3D semiconductor | 3.8 mm (140 keV) | 1 | |
| detector 1 | <1 mm (511 keV) | | |

The 3D detector 100 and the detector system 1 of the embodiments can be used in various medical and non-medical applications including SPECT systems, PET systems, in connection with radiopharmaceuticals, molecular imaging with radionuclide-labeled tracers and Imaging applications outside of medical imaging.

### SPECT

Increased dose efficiency will lead to improved detection of low tracer concentrations. Combined with higher spatial resolution, the detector system 1 enables earlier detection of cancers and metastases, at a stage when treatment has a higher chance of success. The same probe label can be used for targeted drugs, and verification of the efficiency of the treatment can be performed. This can include so-called click chemistry, which can dramatically reduce the time it takes for the drug to reach the cancer target. The affinity to cancer is often low which prolongs the time for the labelled molecule to reach its target. If an intermediary click molecule is injected beforehand, it can attach to cancer over time without any risk to healthy tissue since there is no drug attached. In the second stage, the drug labelled with the click molecule can be injected and will quickly attach to the corresponding click target in the cancer with high affinity. Some click molecules can be labelled with radionuclides for imaging and much higher image quality will assist in optimizing the treatment.

Dynamic imaging is often not possible today due to limited statistics. However, the detector system 1 of the embodiments could enable this. If the efficiency of the detector system 1 is improved by a factor of 10⁶ as compared to prior art SPECT systems, in the same 10-minute time used today for a single image, this examination time can be split in a time series of 10⁶ consecutive 0.6 ms images. The uptake as a function of time often contains valuable diagnostic information.

The detector system 1 of the embodiment would also allow a dramatic reduction of the examination time as compared to prior art SPECT systems. Examinations taking between 10 min and 1 hour today could be reduced to <10 seconds and still have improved image quality. The long image time is particularly burdensome for very sick patients and sometimes prevents an examination from taking place. It would also increase the throughput in the clinic as well as allow research studies with more subjects.

Blurring of the image due to patient motion is a major limitation in diagnostic image quality today. Shortening the image acquisition will reduce the risk of motion artifacts. More importantly, the drastic improvement in efficiency will enable image acquisitions of <1 second that can be synchronized with the heart activity through electrocardiogram (ECG). Having access to a consecutive series of high image quality images will enable advanced methods for motion correction.

The increase in efficiency will also enable extreme low-dose imaging. The effective dose today for a SPECT examination is in the order of 0.5-25 mSv (excluding CT) and keeping other parameters, such as image acquisition time, the same an increased efficiency of 10⁶ would lead to a reduction in radiation dose to 5-25 nSv. The daily radiation dose from natural sources is around 9 nSv, and, thus, the radiation dose burden and risk with a SPECT examination performed with the detector system 1 of the embodiments would be almost negligible. Clinical trials for drug discovery using SPECT are often limited by the radiation risk and this will open up for more subjects and/or more follow up examinations. The cost of the labeled agent would also be much lower. This could translate into new opportunities such as screening for early cancer detection or other diseases.

SPECT today is limited in energy range since the collimator is a necessary component for geometrical accuracy. Even though high energy collimators with thicker walls are available—at some point around 300 keV they become inefficient and photon penetration of the walls become problematic. If use of higher energy gamma radiotracers can be enabled with the detector system 1 of the embodiments, this would result in less scatter in the object.

The spatial resolution would approach X-ray imaging, which adds important information when combining the anatomical image from CT or MR with a functional image from the detector system.

In general, the detector system 1 of the embodiments would open multimodality examinations with PET and other modalities, such as SPECT and PET modalities.

### PET

The detector system 1 of the embodiments could add features to PET systems, such as a much higher spatial resolution detector. Since PET requires two 511 keV photons, it is enough if one of them scatters in the object for the event to be lost. This is very common and for large patients; more than 95% of the events are lost. With the detector system 1 of the embodiments the events with only one scattered gamma ray can be used, corresponding to a significant efficiency gain.

### Radiopharmaceuticals

Radiopharmaceuticals can also be labeled with radionuclides that deposit more energy in the tissues where they are taken up, compared to those used for purely diagnostic purposes. This provides so-called targeted radionuclide therapy (Sgouros et al., 2020). Two examples are lutetium-177-Dotate (¹⁷⁷Lu-Dotatate), which is used for the treatment of neuroendocrine tumors, and 131I-MIBG, which is used for the treatment of neuroblastoma. ¹⁷⁷Lu emits both electrons and 208 keV photons. ¹³¹I emits both electrons and 364 keV photons. The electrons give a local radiation treatment whilst the photons can be imaged using the detector system 1 of the embodiments, making it possible to image the treatment in real-time. This allows the assessment of treatment response, evaluation of tumor regression or progression, and optimization of subsequent treatment plans. Generally, activity levels for radiopharmaceutical treatment are in the range of 4-20 GBq, considerably higher than for imaging.

Metastatic cancer is difficult to treat, and targeted radionuclide therapy is one method that has shown good results and is gaining popularity. Conventional radiotherapy in combination with surgery can only be used when the cancer is localized. Some examples are iodine-131 (¹³¹I) for hyperthyroidism, thyroid cancer, and non-Hodgkin's lymphoma, radium-223 (²²³Ra) for bone metastases, lutetium-177 (¹⁷⁷Lu) for neuroendocrine tumors, yttrium-90 (⁹⁰Y) for non-Hodgkin's lymphoma and liver cancer. All these isotopes beta decay, and the radiation dose is provided by the emitted electron with a typical range of 2 mm to 5 mm. As the electron slows down, it causes emission of so-called bremsstrahlung, which has a continuous energy distribution from zero to the energy of the electron, ranging from 100 keV to 1000 keV. In connection with the decay, high energy gamma photons are also emitted. The radiation emitted at each decay is an opportunity to monitor the therapy as well as obtain diagnostic images showing the status of the cancer as the therapy is delivered. Actinium-225 (²²⁵Ac) is used for targeted alpha therapy for prostate cancer and the emitted alpha particle, with a range <100 μm, is not associated with any bremsstrahlung. The alpha decay of ²²⁵Ac triggers a chain of events associated with gamma emission, for example at 440 keV that can be used for imaging. The energy of the gamma rays associated with targeted radionuclide therapy is high and challenging to image with today's Anger cameras. The performance of the detector system 1 of the embodiments is stable for higher energies and adding a high-resolution diagnostic method to the therapy can be a game-changer in calculating the local radiation dose and optimizing the treatment at an individual level.

Molecular Imaging with Radionuclide-Labeled Tracers

A multitude of radionuclide-labeled tracers are available for imaging physiological and pathophysiological processes in the human body, most commonly technetium-99m (^{99m}Tc) at 140 keV but also at higher energies, such as iodine-131 (¹³¹I) at 364 keV. In principle, isotopes associated with higher energies, several MeV, could also be used, but with today's instrumentation, they are hard to detect. The detector system 1 of the embodiments could, however, be used with such isotopes with higher energies.

The detector system 1 of the embodiments can be used for molecular imaging using multiple different radionuclides. Such an approach enables monitoring of multiple biological processes at the same time in an object, typically an animal subject and more preferably a human subject.

### Imaging Applications Outside of Medical Imaging

The detector system 1 of the embodiments could be used for environmental monitoring or homeland security applications, tracking dedicated molecules. Also, application in astronomy could work, potentially in conjunction with recently invented x-ray optics (Mi et al., 2019).

The embodiments described above are to be understood as a few illustrative examples of the present invention. It will be understood by those skilled in the art that various modifications, combinations and changes may be made to the embodiments without departing from the scope of the present invention. In particular, different part solutions in the different embodiments can be combined in other configurations, where technically possible.

### REFERENCES

Caputo, All-sky Medium Energy Gamma-ray Observatory explorer mission concept, J. Astron. Telesc Instrum. Syst. 2022 8 (4): 044003-1
Corradino et al., Design and Characterization of Backside Termination Structures for Thick Fully-Depleted MAPS, Sensors 2021 21:3809
Corradino et al., Charge Collection Dynamics of the ARCADIA Passive Pixel Arrays: Laser Characterization and TCAD Modeling, Front. Phys. 2022 10:929251
Corradino et al., ARCADIA MAPS process qualification through the electrical characterization of passive pixel arrays, Journal of Instrumentation 2023 18: C02045
Corradino et al., Simulation and first characterization of MAPS test structures with gain for timing applications, Journal of Instrumentation 2024 19: C02036
Daniel et al., Application of a deep learning algorithm to Compton imaging of radioactive point sources with a single planar CdTe pixelated detector, Nuclear Engineering and Technology, 2022 54:1747-1753
De Cilladi et al., Fully Depleted Monolithic Active Microstrip Sensors: TCAD Simulation Study of an Innovative Design Concept, Sensors 2021 21:1990
Kozani and Magiera, Machine learning-based event recognition in SiFi Compton camera imaging for proton therapy monitoring, Phys. Med. Biol. 2022 67:155012
Kroeger et al., Three-Compton Telescope: Theory, Simulations, and Performance, IEEE Transactions on Nuclear Science, 2002 49 (4): 1887-1892
Lee et al., Evaluation of sequence tracking methods for Compton cameras based on CdZnTe arrays, Nuclear Engineering and Technology, 2021 53:4080-4092
Martin et al., A ring Compton scatter camera for imaging medium energy gamma rays, IEEE Transactions on Nuclear Science, 1993 40 (4): 972-978
Matscheko et al., Compton spectroscopy in the diagnostic x-ray energy range. II. Effects of scattering material and energy resolution, Phys Med Biol. 1989 34 (2): 199-208
Maxim et al., Analytical inversion of the Compton transform using the full set of available projections, Inverse Problems, 2009 25 (9): 095001
Maxim, Filtered backprojection reconstruction and redundancy in Compton camera imaging, IEEE Trans. Image Process., 2014 23 (1): 332-341
Mi et al., A stacked prism lens concept for next-generation hard X-ray telescopes, Nature Astronomy 2019 3:867-872
Neubüser et al., Sensor design optimization of innovative low-power, large area FD-MAPS for HEP and applied science, Front. Phys. 2021 9:625401
Neubüser et al., Impact of X-ray induced radiation damage on FD-MAPS of the ARCADIA project, Journal of Instrumentation 2022 17: C01035
Neubüser et al., ARCADIA FD-MAPS: Simulation, characterization and perspectives for high resolution timing applications, Nuclear Inst. And Methods in Physics Research, A 2023a 1048:167946
Neubüser et al., First characterization results of ARCADIA FD-MAPS after X-ray irradiation, Journal of Instrumentation 2023b 18: C01066
Ordonez et al., Angular uncertainties due to geometry and spatial resolution in Compton cameras, 1998 IEEE Nuclear Science Symposium Conference Record. 1998 IEEE Nuclear Science Symposium and Medical Imaging Conference (Cat. No. 98CH36255), Toronto, ON, Canada, 1998, vol. 3, pp. 1535-1540
Pancheri et al., Design of CMOS Monolithic Avalanche Detectors for charged-particle timing with sub-nanosecond resolution, IEEE EUROCON 2023-20th International Conference on Smart Technologies, 6-8 Jul. 2023
Peric et al., High-Voltage CMOS Active Pixel Sensor, IEEE Journal of Solid-State Circuits, 2021 56 (8): 2488-2502
Sgouros et al., Radiopharmaceutical therapy in cancer: clinical advances and challenges, Nat Rev Drug Discov., 2020 19:589-608
Sundberg et al., 1-μm spatial resolution in silicon photon-counting CT detectors, J. Med. Imag. 2021 8 (6): 063501
Sundberg et al., Compton coincidence in silicon photon-counting CT detectors, Journal of Medical Imaging, 2022, 9 (1): 013501
Taschenov and Gerl, TANGO-New tracking AlGOrithm for gamma-rays, Nuclear Instruments and Methods in Physics Research A, 2010, 622:592-601
Takashima et al., Event reconstruction of Compton telescopes using a multi-task neural network, Nuclear Inst. And Methods in Physics Research A, 2022, 1038:166897
Wilderman et al., List-Mode Maximum Likelihood Reconstruction of Compton Scatter Camera Images in Nuclear Medicine, IEEE Conference Record of Nuclear Science Symposium 1998 3:1716-1720
Yao et al., Technical note: Rapid and high-resolution deep learning-based radiopharmaceutical imaging with 3D-CZT Compton camera and sparse projection data, Med Phys. 2022; 49:7336-7346
Yoneda et al., Reconstruction of multiple Compton scattering events in MeV gamma-ray Compton telescopes towards GRAMS: The physics-based probabilistic model, Astroparticle Physics, 2023, 144:102765

What is claimed is:

1. A sensor stack for molecular imaging of an object emitting radiation from radioactive nucleotides, the sensor stack comprising:
multiple sensor pairs superimposed on top of each other, wherein each sensor pair of the multiple sensor pairs comprises:
a first sensor chip made of silicon and comprising:
a pixelized main side comprising a plurality of pixels and integrated complementary metal-oxide-semiconductor, CMOS, electronics electrically connected to the plurality of pixels; and
a high voltage main side opposite to the pixelized main side;
a first connector electrically connected to the integrated CMOS electronics of the first sensor chip;
a second sensor chip made of silicon and comprising:
a pixelized main side comprising a plurality of pixels and integrated CMOS electronics electrically connected to the plurality of pixels; and
a high voltage main side opposite to the pixelized main side;
a second connector electrically connected to the integrated CMOS electronics of the second chip, wherein the first and second sensor chips are superimposed on top of each other with the high voltage main sides of the first and second sensor chips facing each other and with a gap therebetween;
a connector board electrically connected to the first and second connectors of the multiple sensor pairs.

2. The sensor stack according to claim 1, wherein
the first connector is attached the pixelized main side of the first sensor chip and protrudes beyond an edge of the first sensor chip, and
the second connector is attached the pixelized main side of the second sensor chip and protrudes beyond an edge of the second sensor chip.

3. The sensor stack according to claim 1, wherein
the first connector is laterally offset along an edge of the first sensor chip, and
the second connector is laterally offset along an edge of the second sensor chip.

4. The sensor stack according to claim 3, wherein
the first connector is laterally offset along the edge of the first sensor chip with a first distance to a first side edge of the sensor pair and a second distance to a second side edge of the sensor pair, wherein the first distance is different from the second distance, and wherein the first side edge is opposite to the second side edge, and
the second connector is laterally offset along the edge of the second sensor chip with the second distance to the first side edge of the sensor pair and the first distance to the second side edge of the sensor pair.

5. The sensor stack of claim 1, wherein
the first connector is electrically connected to the high voltage main side of the first sensor chip, and
the second connector is electrically connected to the high voltage main side of the second sensor chip.

6. The sensor stack of claim 1, wherein each sensor pair of the multiple sensor pairs comprises a first high voltage connector electrically connected to the high voltage main side of the first sensor chip, wherein the first high voltage connector is electrically connected to the connector board.

7. The sensor stack of claim 6, wherein the first high voltage connector is aligned with the first connector.

8. The sensor stack of claim 6, wherein the first high voltage connector is electrically connected to the high voltage main side of the second sensor chip.

9. The sensor stack of claim 6, wherein each sensor pair of the multiple sensor pairs comprises a second high voltage connector electrically connected to the high voltage main side of the second sensor chip, wherein the second high voltage connector is electrically connected to the connector board.

10. The sensor stack of claim 9, wherein the second high voltage connector is aligned with the second connector.

11. The sensor stack of claim 1, wherein
the first connector comprises a plurality of connector pins,
the second connector comprises a plurality of connector pins, and
the connector board comprises, for each first connector and second connector, a plurality of through holes or female headers arranged to receive the plurality of connector pins.

12. The sensor stack of claim 1, wherein
the first connector comprises a connection edge comprising a plurality of vias,
the second connector comprises a connection edge comprising a plurality of vias, and
the connector board comprises, for each first connector and second connector, a plurality of matching pads arranged to electrically connect to the plurality of vias.

13. The sensor stack of claim 1, wherein
the first connector is a first angled connector comprising a connector side that is angled relative to the pixelized main side and the high voltage main side of the first sensor chip, wherein the connector side comprises a plurality of vias,
the second connector is a second angled connector comprising a connector side that is angled relative to the pixelized main side and the high voltage main side of the second sensor chip, wherein the connector side comprises a plurality of vias, and
the connector board comprises, for each first connector and second connector, a plurality of matching pads arranged to electrically connect to the plurality of vias.

14. The sensor stack of claim 1, wherein each sensor pair of the multiple sensor pairs comprises:
a first interface board electrically connected to the first connector and electrically connected to the connector board, wherein the first interface board is arranged as an electric connection bridge between the first connector and the connector board, and
a second interface board electrically connected to the second connector and electrically connected to the connector board, wherein the second interface board is arranged as an electric connection bridge between the second connector and the connector board.

15. The sensor stack of claim 1, wherein the first and second connectors are selected from the group consisting of printed electronics, printed circuit boards (PCBs), chip-on-film (COFs), molded interconnect devices (MIDs), wafer-level fan-outs (WLFOs).

16. The sensor stack of claim 1, wherein the connector board is a connector printed circuit board.

17. The sensor stack of claim 1, wherein the first sensor chip is attached to the second sensor chip.

18. The sensor stack of claim 17, wherein the first sensor chip is attached by adhesive to the second sensor chip.

19. The sensor stack of claim 18, wherein the adhesive comprises spacer particles.

20. The sensor stack of claim 17, wherein the first sensor chip is attached by adhesive to the second sensor chip at multiple spatially separated attachment points along a circumference of the first and second sensor chips.

21. The sensor stack of claim 1, further comprising a motherboard electrically connected to the connector board.

22. The sensor stack according to claim 1, wherein the first and second sensor chips are made of crystalline silicon with a resistivity exceeding 5 Ωm.

23. A three-dimensional (3D) detector for molecular imaging of an object emitting radiation from radioactive nucleotides, wherein the 3D detector comprises an array or matrix of multiple sensor stacks according to claim 1.

24. A detector system for molecular imaging of a radionuclide comprising:
a 3D detector according to claim 23;
a read-out circuitry connected to the connector PCB and configured to output, for each pixel along an electron track in the 3D detector, a pixel value representative of an energy deposited at the pixel by a Compton recoil electron along the electron track in the 3D detector, wherein the Compton recoil electron is created by a Compton scatter interaction induced by an incident gamma ray in the 3D detector;
at least one processor; and
at least one memory comprising instructions, which when executed by the at least one processor, cause the at least one processor to predict a position of a start of the electron track based on a distribution of the energies deposited at each pixel along the electron track in the 3D detector.
